(19) United States
(12) Patent Application Publication
(10) Pub. No.: US 2025/0212567 A1
(43) Pub. Date: Jun. 26, 2025

(54) DISPLAY DEVICE

(71) Applicant: Samsung Display Co., LTD., Yongin-si (KR)

(72) Inventors: Ji Wook MOON, Yongin-si (KR); Jong Moo HUH, Yongin-si (KR); Min Woo KIM, Yongin-si (KR); Young Kyo SEO, Yongin-si (KR); Gwang Geun LEE, Yongin-si (KR)

(21) Appl. No.: 18/796,929

(22) Filed: Aug. 7, 2024

(30) Foreign Application Priority Data
Dec. 26, 2023 (KR) 10-2023-0190868

(51) Int. Cl. H01L 33/50; H01L 25/075; H01L 33/32; H01L 33/38

(52) U.S. Cl. CPC H10H 20/8512; H01L 25/0753; H10H 20/825; H10H 20/8316; H10H 20/8515

(57) ABSTRACT

A display device includes: a first sub-pixel including a first first-type light emitting element configured to emit light in a blue wavelength band, the first sub-pixel being configured to emit light in the blue wavelength band; a second sub-pixel configured to emit light in a green wavelength band; and a third sub-pixel including a second first-type light emitting element configured to emit light in the blue wavelength band, a third-type light emitting element configured to emit light in a red wavelength band, and a first wavelength conversion layer, the third sub-pixel being configured to emit light in the red wavelength band. A threshold voltage of the third-type light emitting element is lower than a threshold voltage of the second first-type light emitting element.

### CROSS-REFERENCE TO RELATED APPLICATION

The present application claims priority to and the benefit of Korean Patent Application No. 10-2023-0190868, filed on Dec. 26, 2023, in the Korean Intellectual Property Office, the entire disclosure of which is incorporated herein by reference.

### BACKGROUND

### 1. Field

The present disclosure relates to a display device.

### 2. Description of the Related Art

As the information society develops, the demand for display devices for displaying images is increasing in various forms. In response to this, various types of display devices, including light emitting display devices, are being developed.

A light emitting display device utilize light emitting elements, such as organic light emitting diodes or micro light emitting diodes (hereinafter referred to as “micro light emitting elements”), as light sources for pixels. A highly efficient light emitting element may be used to reduce power consumption of a light emitting display device. However, it may be difficult to precisely control the luminance of low gray levels using high-efficiency light emitting elements. Accordingly, the image quality of the display device may be degraded.

When the light emitting element LE is based on AIGaInP, the red light emitting element has a reliability issue due to the wavelength shifting according to current injection.

In addition, if the light emitting element LE is InGaN-based, it may not be suitable for high-resolution due to its low efficiency, which limits size growth. If the light emitting element LE is based on InGaN, there is a problem that the efficiency is significantly lower, which makes it difficult for the light source to realize brightness and requires an increase in current, which may increase the power consumption of the panel.

### SUMMARY

Therefore, aspects and features of embodiments of the present disclosure are to provide a display device that may improve the reliability of the red light emitting element while reducing power consumption.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes: a first sub-pixel including a first first-type light emitting element configured to emit light in a blue wavelength band, the first sub-pixel being configured to emit light in the blue wavelength band; a second sub-pixel configured to emit light in a green wavelength band; and a third sub-pixel including a second first-type light emitting element configured to emit light in the blue wavelength band, a third-type light emitting element configured to emit light in a red wavelength band, and a first wavelength conversion layer, the third sub-pixel being configured to emit light in the red wavelength band, a threshold voltage of the third-type light emitting element being lower than a threshold voltage of the second first-type light emitting element.

In one or more embodiments, the second sub-pixel may include a second-type light emitting element configured to emit light in the green wavelength band.

In one or more embodiments, the second sub-pixel may include a third first-type light emitting element configured to emit light in the blue wavelength band and a second wavelength conversion layer configured to convert light in the blue wavelength band to light in the green wavelength band.

In one or more embodiments, a luminous efficiency of the second first-type light emitting element may be higher than a luminous efficiency of the third-type light emitting element.

In one or more embodiments, the display device may further include: a blue color filter corresponding to the first sub-pixel and configured to transmit only blue light; a green color filter corresponding to the second sub-pixel and configured to transmit only green light; and a red color filter corresponding to the third sub-pixel and configured to transmit only red light.

In one or more embodiments, the first wavelength conversion layer may be located between the second first-type light emitting element and the third-type light emitting element, and the red color filter, and may include a wavelength conversion material configured to convert light in the blue wavelength band to light in the red wavelength band.

In one or more embodiments, the wavelength conversion material may include a quantum dot or a phosphor.

In one or more embodiments, the first wavelength conversion layer may be located between the second first-type light emitting element and the third-type light emitting element, and the red color filter, and may include a wavelength conversion material configured to convert light in the blue wavelength band and light in the red wavelength band to light in a yellow wavelength band.

In one or more embodiments, the third-type light emitting element may include an InGaN-based element.

In one or more embodiments, the third sub-pixel may include a pixel electrode and a common electrode, the second first-type light emitting element and the third-type light emitting element may be connected between the pixel electrode and the common electrode, and the second first-type light emitting element and the third-type light emitting element may be connected in parallel.

In one or more embodiments, the third sub-pixel may include a pixel electrode and a common electrode, the pixel electrode and the common electrode may be non-overlapping with each other in a thickness direction of the second first-type light emitting element and the third-type light emitting element, a portion of the second first-type light emitting element and a portion of the third-type light emitting element may be on the pixel electrode, and another portion of the second first-type light emitting element and another portion of the third-type light emitting element may be on the common electrode.

In one or more embodiments, the third sub-pixel may include a pixel electrode and a common electrode, the pixel electrode and the common electrode may overlap each other in a thickness direction of the second first-type light emitting element and the third-type light emitting element, the second first-type light emitting element and the third-type light emitting element may be on the pixel electrode, and the common electrode may be on the second first-type light emitting element and the third-type light emitting element.

According to one or more embodiments, a display device includes: a first sub-pixel, a second sub-pixel, and a third sub-pixel that are configured to emit different color lights, wherein the third sub-pixel includes more diverse types of light emitting elements than the first sub-pixel, and wherein the third sub-pixel includes different types of light emitting elements that are configured to emit different color lights and have different threshold voltages.

According to one or more embodiments, a display device includes: a first sub-pixel including a first-type light emitting element configured to emit light in a blue wavelength band, the first sub-pixel being configured to emit light in the blue wavelength band; a second sub-pixel configured to emit light in a green wavelength band; a third sub-pixel including a third-type light emitting element configured to emit light in a red wavelength band, the third sub-pixel being configured to emit light in the red wavelength band; and a fourth sub-pixel including a second first-type light emitting element configured to emit light in the blue wavelength band and a wavelength conversion layer, the fourth sub-pixel being configured to emit light in the red wavelength band, a threshold voltage of the third-type light emitting element being lower than a threshold voltage of the second first-type light emitting element.

In one or more embodiments, the third sub-pixel and the fourth sub-pixel may be adjacent to each other.

In one or more embodiments, a luminous efficiency of the third-type light emitting element may be lower than a luminous efficiency of the second first-type light emitting element.

In one or more embodiments, the second sub-pixel may include a second-type light emitting element configured to emit light in the green wavelength band.

In one or more embodiments, the display device may further include: a blue color filter corresponding to the first sub-pixel and configured to transmit only blue light; a green color filter corresponding to the second sub-pixel and configured to transmit only green light; and a red color filter corresponding to the third sub-pixel and the fourth sub-pixel and configured to transmit only red light.

In one or more embodiments, the wavelength conversion layer may be located between the second first-type light emitting element and the red color filter, and may include a wavelength conversion material configured to convert light in the blue wavelength band to light in the red wavelength band.

In one or more embodiments, the third sub-pixel may include a pixel electrode and a common electrode, and the third-type light emitting element may be connected between the pixel electrode and the common electrode.

According to one or more embodiments, high brightness of the red sub-pixel of the display device may be realized. Thus, the image quality of the display device may be improved while reducing power consumption.

However, the aspects and effects of the present disclosure are not limited to the aforementioned aspects and effects, and various other aspects and effects are included in the present disclosure.

### BRIEF DESCRIPTION OF THE DRAWINGS

FIG. 1 is a perspective view illustrating a display device according to one or more embodiments.

FIG. 2 is a plan view illustrating a display panel according to one or more embodiments.

FIG. 3 is a block diagram illustrating a display device according to one or more embodiments.

FIG. 4 is a circuit diagram illustrating a first sub-pixel according to one or more embodiments.

FIG. 5 is a circuit diagram illustrating a first sub-pixel according to one or more embodiments.

FIG. 6 is a circuit diagram illustrating a third sub-pixel according to one or more embodiments.

FIG. 7 is a plan view illustrating sub-pixels according to one or more embodiments.

FIG. 8 is a cross-sectional view illustrating a display panel according to one or more embodiments.

FIG. 9 is a cross-sectional view illustrating area A1 of FIG. 8 in detail according to one or more embodiments.

FIG. 10 is a cross-sectional view of a display panel corresponding to line X1-X1′ of FIG. 7 according to one or more embodiments.

FIG. 11 is a cross-sectional view illustrating sub-pixels according to one or more embodiments.

FIG. 12 is a plan view illustrating sub-pixels according to one or more embodiments.

FIG. 13 is a cross-sectional view illustrating a display panel according to one or more embodiments.

FIG. 14 is a cross-sectional view of a display panel 100 corresponding to the X2-X2′ lines in FIG. 12 according to one or more embodiments.

FIG. 15 is a plan view illustrating sub-pixels according to one or more embodiments.

FIG. 16 is a cross-sectional view illustrating a display panel according to one or more embodiments.

FIG. 17 is a plan view illustrating sub-pixels according to one or more embodiments.

FIG. 18 is a cross-sectional view illustrating a display panel according to one or more embodiments.

FIG. 19 is a plan view illustrating sub-pixels according to one or more embodiments.

FIG. 20 is a cross-sectional view illustrating a display panel according to one or more embodiments.

FIG. 21 is an example diagram schematically showing a virtual reality device including a display device according to one or more embodiments.

FIG. 22 is an example diagram schematically showing a smart device including a display device according to one or more embodiments.

FIG. 23 is a diagram of an example schematically showing a vehicle including a display device according to one or more embodiments.

FIG. 24 is a diagram of an example schematically showing a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts that are not associated with the description may not be provided in order to describe embodiments of the disclosure. Some of the parts that are not necessary for a complete understanding of the present disclosure by a person having ordinary skill in the art may also be omitted.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” or “at least one of A or B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific embodiments will be described with reference to the accompanying drawings.

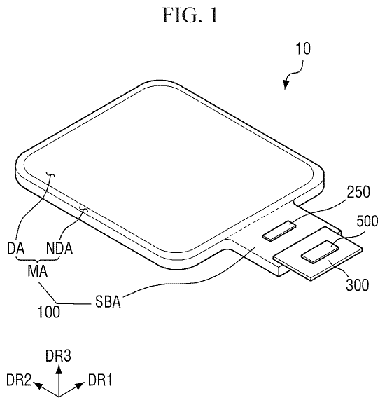

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and/or the internet of things (IoT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation. However, types of light emitting elements that may be applied to the embodiments are not limited to ultra-small light emitting diodes.

The display device 10 includes a display panel 100, a display driving circuit 250, a circuit board 300, and a power supply circuit 500.

The display panel 100 may have a rectangular or square planar shape with sides extending in the first direction DR1 and sides extending in the second direction DR2 intersecting the first direction DR1. A corner where the sides in the first direction DR1 and the sides in the second direction DR2 meet may be rounded to have a suitable curvature (e.g., a predetermined curvature) or may be formed at a right angle. The planar shape of the display panel 100 is not limited to a square or rectangular shape. For example, the display panel 100 may have a different planar shape, such as a polygon, circle, or oval. The display panel 100 may be formed flat but is not limited thereto. For example, the display panel 100 may be formed at left and right ends and may include curved portions with a constant curvature or a varying curvature. In one or more embodiments, the display panel 100 may be flexible so that it may be bent, twisted, bent, folded, and/or rolled.

The substrate SUB of the display panel 100 may include a main area MA and a sub-area SBA.

The main area MA may include a display area DA that displays an image and a non-display area NDA that is a peripheral area of the display area DA and is around (e.g., surrounding) the display area DA along an edge or a periphery of the display area DA. The display area DA may include the pixels that display an image. In one or more embodiments, each pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, the main area MA and the sub-area SBA may overlap in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip-on-glass (COG) method, a chip-on-plastic (COP) method, or an ultrasonic bonding method but is not limited thereto. In one or more embodiments, the display driving circuit 250 may be attached to the circuit board 300 using a chip-on-film (COF) method.

The circuit board 300 may be attached to one end of the sub-area SBA of the display panel 100. In one or more embodiments, the circuit board 300 may be attached to pads of the display panel 100 located at one end of the sub-area SBA. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip-on-film (COF).

The power supply circuit 500 (e.g., power supply unit) may generate and/or supply panel driving voltages according to a power voltage supplied from the outside. The power supply circuit 500 may be formed as an integrated circuit (IC) and attached to the circuit board 300 using a COF method.

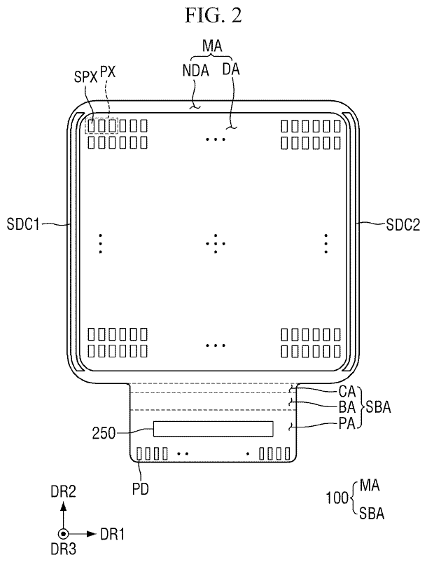

FIG. 2 is a plan view illustrating a display panel according to one or more embodiments. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include unit pixels PX for displaying an image, and each unit pixel PX may include a plurality of sub-pixels SPX (or pixels). A unit pixel PX may be defined as the smallest sub-pixel group capable of expressing a white grayscale (e.g., a while color).

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit (or a first scan driving portion) SDC1 and a second scan driving unit (or a second scan driving portion) SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, the present disclosure is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be bent, and thus a portion of the sub-area SBA may be disposed below the main area MA. For example, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA (e.g., in a thickness direction (e.g., the third direction DR3)). The bending area BA may be disposed between the connection area CA and the pad area PA. One side of the bending area BA may be in contact with the connection area CA, and the other side of the bending area BA may be in contact with the pad area PA.

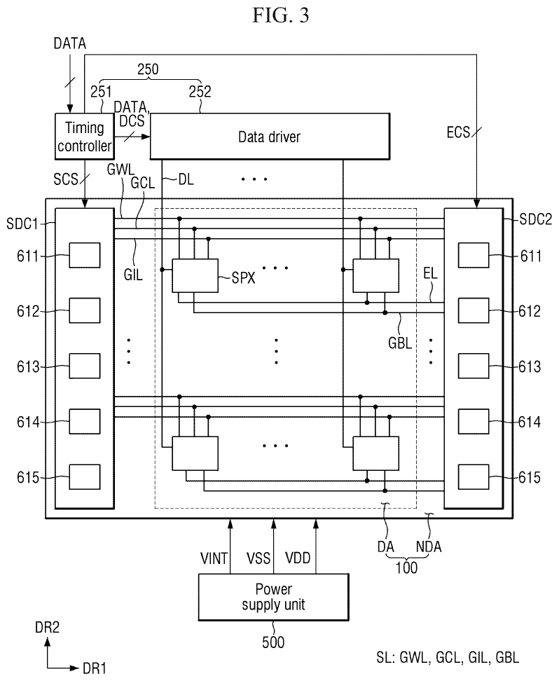

FIG. 3 is a block diagram illustrating a display device according to one or more embodiments.

Referring to FIGS. 1-3, the display area DA may include unit pixels PX including each sub-pixel SPX, scan lines SL, emission control lines EL, and data lines DL connected to the sub-pixels SPX.

The sub-pixels SPX may be arranged in a matrix form in the first direction DR1 and the second direction DR2. The scan lines SL and the emission control lines EL may extend in the first direction DR1 and be arranged along the second direction DR2. The data lines DL may extend in the second direction DR2 and may be arranged along the first direction DR1. The scan lines SL may include write scan lines GWL, control scan lines GCL, initialization scan lines GIL, and bias scan lines GBL disposed in each pixel row.

Each of the sub-pixels SPX may be connected to one of the write scan lines GWL, one of the control scan lines GCL, one of the initialization scan lines GIL, one of the bias scan lines GBL, one of the emission control lines EL, and one of the data lines DL. For example, each sub-pixel SPX may be connected to a write scan line GWL, a control scan line GCL, an initialization scan line GIL, a bias scan line GBL, and an emission control line EL disposed in each pixel row, and a data line DL disposed in each pixel column.

Each of the sub-pixels SPX may be supplied with a data signal (e.g., a data voltage) on the data line DL according to the write scan signal supplied through the write scan line GWL, and may operate the light emitting element according to the data signal.

The first scan driving unit SDC1, the second scan driving unit SDC2, and the display driver circuit 250 may be disposed in the non-display area NDA.

Each of the first scan driving unit SDC1 and the second scan driving unit SDC2 may include a write scan signal output unit 611, a control scan signal output unit 612, an initialization scan signal output unit 613, a bias scan signal output unit 614, and a light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit 251. The write scan signal output unit 611 may generate write scan signals according to the scan timing control signal SCS of the timing control circuit 251 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines GBL. The light emitting signal output unit 615 may generate light emitting control signals according to the scan timing control signal SCS and sequentially output them to the emission control lines EL.

The display driving circuit 250 may include a timing control circuit (or a timing controller) 251 and a data driving circuit (or a data driver) 252.

The timing control circuit 251 may receive video data DATA (e.g., digital video data) and timing signals from the outside (e.g., from an external device). The timing control circuit 251 may generate a scan timing control signal SCS and a data timing control signal DCS to control the display panel 100 according to timing signals. The timing control circuit 251 may output the scan timing control signal SCS to the first scan driving unit SDC1 and the second scan driving unit SDC2. The timing control circuit 251 may output video data DATA and a data timing control signal DCS to the data driving circuit 252.

The data driving circuit 252 may receive video data DATA and a data timing control signal DCS from the timing control circuit 251. The data driving circuit 252 may supply respective data signals (e.g., analog data voltages) to the sub-pixels SPX. For example, the data driving circuit 252 may convert video data DATA into analog data voltages according to the data timing control signal DCS and output them to the data lines DL. The sub-pixels SPX may be selected by the write scan signals of the first scan driving unit SDC1 and the second scan driving unit SDC2, and data signals may be supplied to the selected sub-pixels SPX.

The power supply circuit 500 may generate a plurality of panel driving voltages according to an external power supply voltage. For example, the power supply circuit 500 may generate and/or supply a first driving voltage VDD, a second driving voltage VSS, and a third driving voltage VINT to the display panel 100.

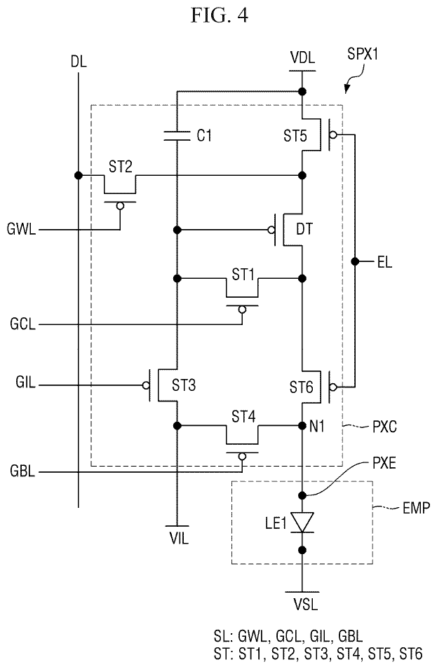

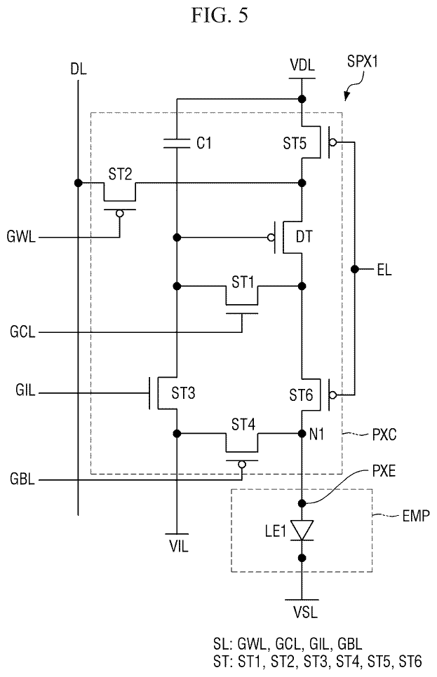

FIG. 4 is a circuit diagram illustrating a first sub-pixel according to one or more embodiments. FIG. 5 is a circuit diagram illustrating a first sub-pixel according to one or more embodiments. Compared to FIG. 4, FIG. 5 shows one or more embodiments in which some of the transistors have been re-typed (e.g., some of the transistors have been changed from P-type transistors to N-type transistors). Because the circuit diagram of the second sub-pixel is substantially the same as that of the first sub-pixel, the description of the second sub-pixel will not be separately provided with the understanding that FIGS. 4 and 5 would also substantially show the circuit diagram of the second sub-pixel according to respective embodiments.

Referring to FIGS. 4 and 5, the first sub-pixel SPX1 according to one or more embodiments may be connected between the first power supply line VDL and the second power supply line VSL and may include a light emitting portion EMP. The first sub-pixel SPX1 and the second sub-pixel SPX2 may further include a pixel circuit PXC connected to the light emitting element LE (e.g., LE1 in FIGS. 4 and 5). In one or more embodiments, the pixel circuit PXC may be connected between the first power supply line VDL and the light emitting portion EMP.

The pixel circuit PXC may be connected to the scan lines SL, the emission control line EL, and the data line DL. For example, the pixel circuit PXC may be connected to a write scan line GWL, an initialization scan line GIL, a control scan line GCL, a bias scan line GBL, an emission control line EL, and a data line DL.

The pixel circuit PXC may include a driving transistor DT, at least one switching transistor ST, and a capacitor C1. In one or more embodiments, the pixel circuit PXC may include first to sixth transistors ST1, ST2, ST3, ST4, ST5, and ST6 as the switching transistor ST. The configuration of the pixel circuit PXC is not limited to the embodiments of FIGS. 4 and 5 and may be changed in various ways known to a person having ordinary skill in the pertinent art.

The driving transistor DT includes a gate electrode, a first electrode, and a second electrode. The driving transistor DT may be controlled to provide a drain-to-source current (Ids, hereinafter referred to as the “driving current”) that flows between the first electrode of the driving transistor DT and the second electrode of the driving transistor DT according to a data signal (e.g., an analog data voltage) applied to the gate electrode of the driving transistor DT.

The first transistor ST1 may be connected between the second electrode and the gate electrode of the driving transistor DT, and the gate electrode of the first transistor ST1 may be connected to the control scan line GCL. The first transistor ST1 may operate as a switch according to the control scan signal supplied to the control scan line GCL.

The second transistor ST2 may be connected between the data line DL and the first electrode of the driving transistor DT, and the gate electrode of the second transistor ST2 may be connected to the write scan line GWL. The second transistor ST2 may operate as a switch according to the write scan signal supplied to the write scan line GWL.

The third transistor ST3 may be connected between the gate electrode of the driving transistor DT and the initialization voltage line VIL, and the gate electrode of the third transistor ST3 may be connected to the initialization scan line GIL. The third transistor ST3 may operate as a switch according to the initialization scan signal supplied to the initialization scan line GIL. A third driving voltage VINT may be applied to the initialization voltage line VIL.

The fourth transistor ST4 may be connected between the first node N1 and the initialization voltage line VIL, and the gate electrode of the fourth transistor ST4 may be connected to the bias scan line GBL. The first node N1 may be a node where the pixel circuit PXC and the light emitting portion EMP are connected to each other. For example, the first node N1 may be a node where the fourth transistor ST4 and the sixth transistor ST6 of the pixel circuit PXC, and the pixel electrode PXE (e.g., an anode electrode of the light emitting element LE1) of the light emitting portion EMP are connected to each other. The fourth transistor ST4 may operate as a switch according to the bias scan signal supplied to the bias scan line GBL.

The fifth transistor ST5 may be connected between the first power supply line VDL and the first electrode of the driving transistor DT, and the gate electrode of the fifth transistor ST5 may be connected to the emission control line EL. The fifth transistor ST5 may operate as a switch according to the emission control signal supplied to the emission control line EL. The first driving voltage VDD may be applied to the first power supply line VDL.

The sixth transistor ST6 may be connected between the second electrode of the driving transistor DT and the first node N1, and the gate electrode of the sixth transistor ST6 may be connected to the emission control line EL. The sixth transistor ST6 may operate as a switch according to the emission control signal supplied to the emission control line EL.

In one or more embodiments, as shown in FIG. 4, the driving transistor DT and the first to sixth transistors ST1, ST2, ST3, ST4, ST5, and ST6 may be formed of P-type transistors. In one example, the driving transistor DT and each of the first to sixth transistors ST1, ST2, ST3, ST4, ST5, and ST6 may be formed of a P-type MOSFET including an active layer formed of polysilicon.

In one or more embodiments, as shown in FIG. 5, the driving transistor DT, the second transistor ST2, the fourth transistor ST4, the fifth transistor ST5, and the sixth transistor ST6 may be formed of P-type transistors, and the first transistor ST1 and the third transistor ST3 may be formed of N-type transistors. In one example, each of the driving transistor DT, the second transistor ST2, the fourth transistor ST4, the fifth transistor ST5, and the sixth transistor ST6 may be formed as a P-type MOSFET with an active layer formed of polysilicon, and each of the first transistor ST1 and the third transistor ST3 may be formed as an N-type MOSFET with an active layer formed of an oxide semiconductor. In one or more embodiments, the transistors including active layers formed of polysilicon and the transistors including active layers formed of an oxide semiconductor may be disposed in (or at) different layers within the display panel 100.

Alternatively, although not shown in FIGS. 4 and 5, the driving transistor DT and the first to sixth transistors ST1, ST2, ST3, ST4, ST5, and ST6 may be formed of N-type transistors. In one example, the driving transistor DT and each of the first to sixth transistors ST1, ST2, ST3, ST4, ST5, and ST6 may be formed of an N-type MOSFET including an active layer formed of an oxide semiconductor.

Depending on the type of transistor, the levels of the gate-on voltage and gate-off voltage of the signal (e.g., the respective scan signal, data signal, or light emission control signal) applied to the gate electrode of each transistor may be appropriately set or changed as a person having ordinary skill in the pertinent art would appreciate. For example, the gate-on voltage of a P-type transistor may be a low-level voltage (e.g., a gate-low voltage), and the gate-on voltage of an N-type transistor may be a high-level voltage (e.g., a gate-high voltage).

The capacitor C1 may be connected between the first power supply line VDL and the gate electrode of the driving transistor DT. The capacitor C1 may be charged with a voltage corresponding to the data signal.

The light emitting portion EMP may be connected between the pixel circuit PXC (or the first node N1) and the second power supply line VSL. The light emitting portion EMP may include one or more light emitting elements LE (e.g., LE1 in FIGS. 4 and 5). For example, a first contact electrode (or a first semiconductor layer) of the light emitting element LE may be connected to the pixel circuit PXC through the pixel electrode PXE, and a second contact electrode (or a second semiconductor layer) of the light emitting element LE may be connected to the second power supply line VSL through a common electrode CE (e.g., a cathode electrode). The second power supply line VSL may be applied with the second driving voltage VSS. The second driving voltage VSS may be a voltage at a lower level than the first driving voltage VDD (e.g., applied to the first power supply line VDL). In one or more embodiments, each of the light emitting elements LE may be a micro light emitting diode.

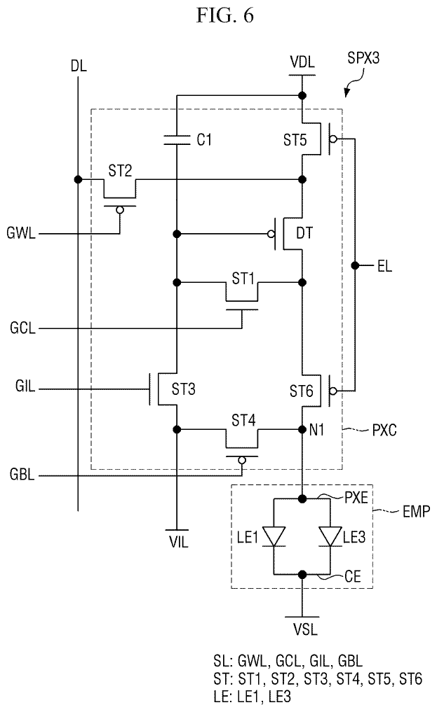

FIG. 6 is a circuit diagram illustrating a third sub-pixel according to one or more embodiments.

FIG. 6 is different from FIGS. 4 and 5 in that the light emitting portion EMP has a plurality of light emitting elements LE (e.g., LE1 and LE3 in FIG. 6). Referring to FIG. 6, the light emitting portion EMP may include a plurality of light emitting elements LE including a first-type light emitting element LE1 and a third-type light emitting element LE3. The light emitting elements LE may be connected between the pixel circuit PXC (or the first node N1) and the second power supply line VSL. For example, the first contact electrodes (or first semiconductor layers) of the light emitting elements LE may be connected to the pixel circuit PXC through the pixel electrode PXE, and the second contact electrodes (or second semiconductor layers) of the light emitting elements LE may be connected to the second power supply line VSL through the common electrode CE (e.g., the cathode electrode). The second driving voltage VSS may be applied to the second power supply line VSL. The second driving voltage VSS may be a voltage at a lower level than the first driving voltage VDD (e.g., applied to the first power supply line VDL). In one or more embodiments, each of the light emitting elements LE may be a micro light emitting diode. The light emitting portion EMP may emit light with a luminance corresponding to the driving current supplied from the pixel circuit PXC.

The first-type light emitting element LE1 and the third-type light emitting element LE3 may be connected in parallel to each other between the pixel electrode PXE and the common electrode CE. Furthermore, the first-type light emitting element LE1 and the third-type light emitting element LE3 may be devices with different characteristics, and the threshold voltage of the first-type light emitting element LE1 and the threshold voltage of the third-type light emitting element LE3 may be different. For example, the threshold voltage of the third-type light emitting element LE3 may be lower than the threshold voltage of the first-type light emitting element LE1.

In one or more embodiments, the pixel circuit PXC may not substantially generate a driving current in response to a data signal corresponding to video data DATA with a black gray level (e.g., zero gray level). In this case, the first-type light emitting element LE1 and the third-type light emitting element LE3 may not operate, and thus the sub-pixel SPX may not emit light.

The pixel circuit PXC may generate a relatively small driving current in response to a data signal (hereinafter referred to as a “low-gray level data signal”) corresponding to video data DATA in a low-gray level range (e.g., 1 to 150 grayscale (or gray levels)) below a reference value (e.g., a predetermined reference value). In one or more embodiments, during the period when the sub-pixel SPX is driven by the low-gray level data signal, a voltage may be applied between the pixel electrode PXE and the common electrode CE that is lower than the threshold voltage of the first-type light emitting element LE1 and higher than the threshold voltage of the second-type light emitting element LE2. Accordingly, the first-type light emitting element LE1 may remain in an off state, and the third-type light emitting element LE3 may emit light. The sub-pixel SPX may emit light at low brightness corresponding to a low-gray level data signal by the operation (e.g., light emission) of the third-type light emitting element LE3.

In one or more embodiments, the third-type light emitting element LE3 may have lower luminous efficiency than the first-type light emitting element LE1. Accordingly, in the third-type light emitting element LE3, the change in current density according to the change in the input signal (e.g., low-gray level data signal) may not occur suddenly but may appear in a relatively gradual form. When the first-type light emitting element LE1 is turned-off and the third-type light emitting element LE3 alone drives the sub-pixel SPX at a low luminance corresponding to the low-gray level data signal, the luminance of the sub-pixel SPX may be more precisely or appropriately controlled in response to each gradation (or gray level) according to the low-gray level data signal. Accordingly, the low-tonal expressiveness of the sub-pixel SPX may be increased and the image quality of the display device 10 may be improved.

The pixel circuitry PXC may generate a relatively large driving current in response to a data signal (hereinafter referred to as a “high-gray level data signal”) corresponding to video data DATA in a high-gray level range (e.g., 151 or more gray levels, or 151 to 255 gray levels) above a reference value. In one or more embodiments, a voltage above the threshold voltage of the first-type light emitting element LE1 may be applied between the pixel electrode PXE and the common electrode CE during the period when the sub-pixel SPX is driven by the high-gray level data signal. Accordingly, both the first-type light emitting element LE1 and the third-type light emitting element LE3 may emit light to express a high brightness gray level corresponding to the data signal.

In one or more embodiments, the first-type light emitting element LE1 may have higher luminous efficiency than the third-type light emitting element LE3. By emitting both the first-type light emitting element LE1 and the third-type light emitting element LE3 in response to the high-gray level data signal, the luminance of the sub-pixel SPX corresponding to each gray level of the high-gray level data signal may be sufficiently or appropriately secured while appropriately limiting the driving current flowing to the sub-pixel SPX. Accordingly, the power consumption of the display device 10 may be reduced or improved.

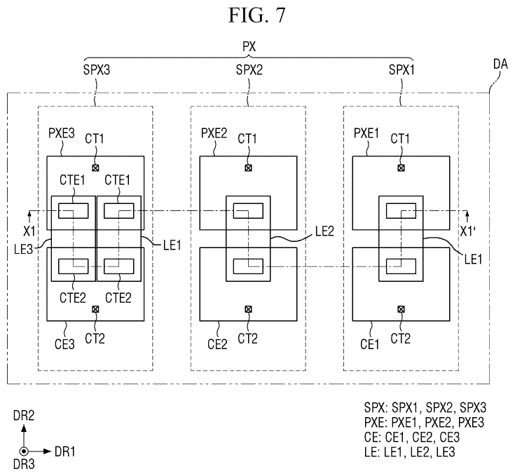

FIG. 7 is a plan view illustrating sub-pixels according to one or more embodiments. For example, FIG. 7 schematically illustrates a light emitting portions EMP of the first sub-pixel SPX1, the second sub-pixel SPX2, and the third sub-pixel SPX3 arranged in the display area DA.

Referring to FIGS. 1-6, each of the unit pixels PX disposed in the display area DA may include a first sub-pixel SPX1, a second sub-pixel SPX2, and a third sub-pixel SPX3. In one or more embodiments, the first sub-pixel SPX1, the second sub-pixel SPX2, and the third sub-pixel SPX3 constituting a unit pixel PX may be arranged in the first direction DR1 but is not limited to this. For example, the arrangement of the sub-pixels SPX may vary depending on the embodiments.

FIG. 7 illustrates an embodiment in which a first sub-pixel SPX1, a second sub-pixel SPX2, and a third sub-pixel SPX3 together constitute a unit pixel PX, but embodiments of the present disclosure are not limited thereto. For example, the type, number, or ratio of sub-pixels SPX constituting each unit pixel PX may vary depending on embodiments.

In addition, while the first sub-pixel SPX1, the second sub-pixel SPX2, and the third sub-pixel SPX3 (or the light emitting areas of the first sub-pixel SPX1, the second sub-pixel SPX2, and the third sub-pixel SPX3) have substantially the same size and shape as each other in FIG. 7, embodiments of the present disclosure are not limited thereto. For example, sizes and/or shapes of the sub-pixels SPX may vary depending on embodiments. For example, the sizes of the sub-pixels SPX may be appropriately adjusted according to the light efficiency of the sub-pixels SPX.

The first sub-pixel SPX1 (which also may be referred to as the “first pixel”) may emit a first light, the second sub-pixel SPX2 (which also may be referred to as the “second pixel”) may emit a second light, and the third sub-pixel SPX3 (which also may be referred to as the “third pixel”) may emit a third light. In one or more embodiments, the first light may be light in a blue wavelength band (e.g., light of a blue wavelength), the second light may be light in a green wavelength band (e.g., light of a green wavelength), and the third light may be light in a red wavelength band (e.g., light of a red wavelength). In one or more embodiments, the first light, the second light, and the third light may respectively be a blue light having a peak wavelength in a range of approximately 440 nm to approximately 480 nm, a green light having a peak wavelength in a range of approximately 510 nm to approximately 550 nm, and a red light having a peak wavelength in a range of approximately 610 nm to approximately 650 nm. The color or wavelength band of light emitted from each sub-pixel SPX may vary depending on embodiments as one having ordinary skill in the art would appreciate.

The sub-pixels SPX may each include a pixel electrode PXE, a common electrode CE, and a light emitting element LE. For example, the first sub-pixel SPX1 may include a first pixel electrode PXE1, a first common electrode CE1, and a first-type light emitting element LE1. The second sub-pixel SPX2 may include a second pixel electrode PXE2, a second common electrode CE2, and a second-type light emitting element LE2. The third sub-pixel SPX3 may include a third pixel electrode PXE3, a third common electrode CE3, a first-type light emitting element LE1, and a third-type light emitting element LE3. In one or more embodiments, the first, second and third common electrodes CE1, CE2 and CE3 may be a single common electrode that is integrally formed.

The pixel electrode PXE and the common electrode CE of each sub-pixel SPX may be arranged to be spaced (e.g., spaced apart) from each other in a respective sub-pixel area. For example, the first pixel electrode PXE1 and the first common electrode CE1 may be arranged to be spaced (e.g., spaced apart) from each other in the light emitting area of the first sub-pixel SPX1. The second pixel electrode PXE2 and the second common electrode CE2 may be arranged to be spaced (e.g., spaced apart) from each other in the light emitting area of the second sub-pixel SPX2. The third pixel electrode PXE3 and the third common electrode CE3 may be arranged to be spaced (e.g., spaced apart) from each other in the light emitting area of the third sub-pixel SPX3.

Each light emitting element LE may be disposed or bonded on a respective one of the pixel electrodes PXE and a respective one of the common electrodes CE. In one example, the pixel electrodes PXE and the common electrodes CE may include bonding pads that are bonded to the respective light emitting elements LE. In one or more embodiments, the pixel electrodes PXE and the common electrodes CE may be metal electrodes including a metal suitable for bonding but embodiments of the present disclosure are not limited thereto.

Although FIG. 7 illustrates one or more embodiments in which each pixel electrode PXE and the common electrode CE have a rectangular planar shape, embodiments of the present disclosure are not limited thereto. Also, although FIG. 7 illustrates one or more embodiments in which each pixel electrode PXE, light emitting element LE, and common electrode CE are formed to have substantially the same size, embodiments of the present disclosure are not limited thereto. For example, shapes and sizes of the pixel electrodes PXE (e.g., PXE1, PXE2, PXE3), light emitting elements LE (e.g., LE1, LE2, LE3), and common electrodes CE (e.g., CE1, CE2, CE3) disposed in the respective sub-pixels SPX (e.g., SPX1, SPX2, SPX3) may vary depending on embodiments. The sub-pixels SPX may have pixel electrodes PXE and/or common electrodes CE of substantially the same size, or the sizes of the pixel electrodes PXE and/or common electrodes CE may be different for different sub-pixels SPX.

Each pixel electrode PXE may be connected to the pixel circuit PXC (e.g., see FIGS. 4, 5 and 6) of the corresponding sub-pixel SPX through a respective first connection hole CT1. For example, the first pixel electrode PXE1 may be connected to the pixel circuit PXC of the first sub-pixel SPX1, the second pixel electrode PXE2 may be connected to the pixel circuit PXC of the second sub-pixel SPX2, and the third pixel electrode PXE3 may be connected to the pixel circuit PXC of the third sub-pixel SPX3.

Each common electrode CE may be connected to the second power supply line VSL to which the second driving voltage VSS is applied through a respective second connection hole CT2. For example, each of the first common electrode CE1, the second common electrode CE2, and the third common electrode CE3 may be connected to the second power supply line VSL through the respective second connection hole CT2. Accordingly, the second driving voltage VSS may be applied to the first common electrode CE1, the second common electrode CE2, and the third common electrode CE3.

Although FIG. 7 illustrates one or more embodiments in which the common electrodes CE of the sub-pixels SPX are individually formed (e.g., separated from each other), the present disclosure is not limited thereto. In one or more other embodiments, the common electrodes CE disposed in the plurality of sub-pixels SPX located in the display area DA may be formed integrally to form one common electrode CE (e.g., a single integrated common electrode CE).

In one or more embodiments, each light emitting element LE may include a first contact electrode CTE1 connected to the respective pixel electrode PXE (e.g., PXE1, PXE2, or PXE3). In one or more embodiments, each light emitting element LE may further include a second contact electrode CTE2 connected to the respective common electrode CE (e.g., CE1, CE2, or CE3).

In one or more embodiments, the first-type light emitting element LE1, the second-type light emitting element LE2, and the third light emitting element LE3 may emit light of different wavelengths (e.g., light in different wavelength bands). For example, the first-type light emitting element LE1 may primarily emit the first light, the second-type light emitting element LE2 may primarily emit the second light, and the third-type light emitting element LE3 may primarily emit the third light. In one or more embodiments, the first light may be light in a blue wavelength band, the second light may be light in a green wavelength band, and the third light may be light in a red wavelength band.

The third sub-pixel SPX3 may include a plurality of light emitting elements LE having different characteristics. For example, the third sub-pixel SPX3 may include a first-type light emitting element LE1 and a third light emitting element LE3 that may be light emitting elements LE having different characteristics from each other. For example, the threshold voltages of the first-type light emitting element LE1 and the third-type light emitting element LE3 may be different from each other. Also, the luminous efficiencies of the first-type light emitting element LE1 and the third-type light emitting element LE3 may be different from each other. In one or more embodiments, the third-type light emitting element LE3 may have a lower threshold voltage and lower light emitting efficiency than the first-type light emitting element LE1.

The third sub-pixel SPX3 may include a greater number of light emitting elements than the first sub-pixel SPX1 or the second sub-pixel SPX2. Accordingly, the size of the light emitting element included in the third sub-pixel SPX3 may be smaller than the size of the light emitting element included in the first sub-pixel SPX1 or the second sub-pixel SPX2 but the present disclosure is not limited thereto.

In one or more embodiments, during a period in which each sub-pixel SPX is driven at low brightness by a data signal corresponding to video data DATA in a low tonal range (e.g., a low gray level range) below a reference value, a low driving current may be applied to a third-type light emitting element LE3 having a relatively low luminous efficiency to cause the third-type light emitting element LE3 to emit at a luminance corresponding to each tonal range (e.g., each gray level range). During the period in which each sub-pixel SPX is driven at high brightness by a data signal corresponding to video data DATA in a high gradation range (or a high gray level range) greater than the reference value, the driving current may be appropriately limited by emitting the third-type light emitting element LE3 as well as the first-type light emitting element LE1 with a relatively high luminous efficiency. Accordingly, the sub-pixel SPX may be appropriately emitted with high brightness corresponding to each gradation (or each gray level) while reducing or improving power consumption.

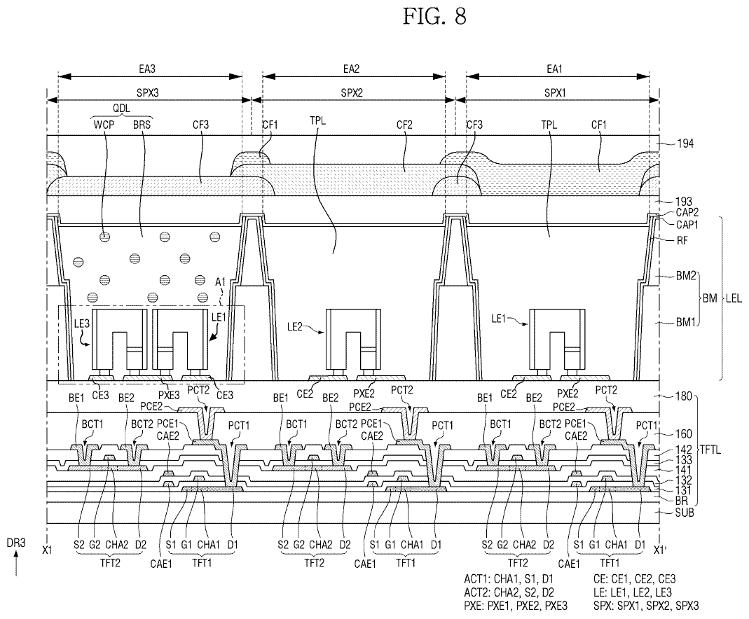

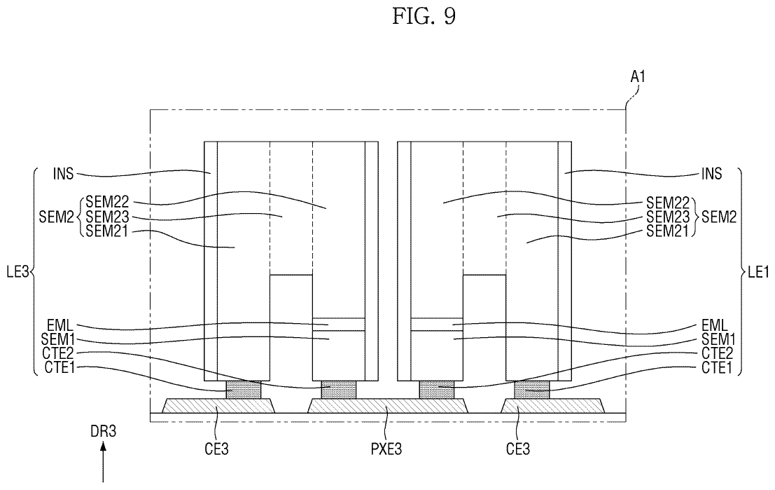

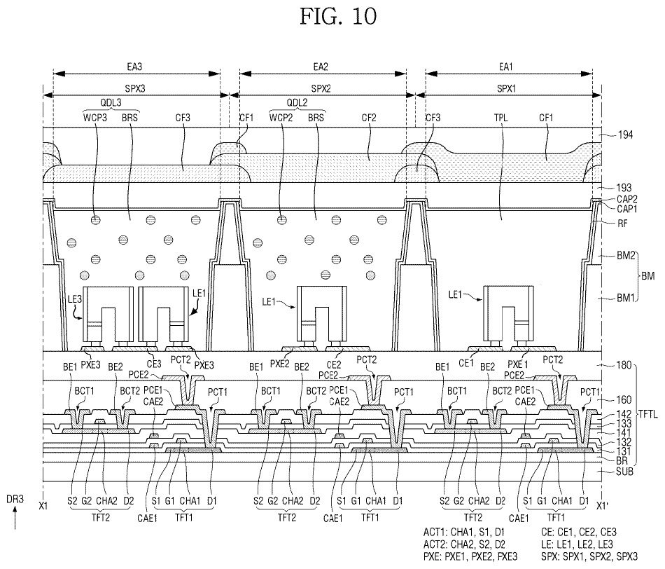

FIG. 8 is a cross-sectional view illustrating a display panel according to one or more embodiments. For example, FIG. 8 illustrates one example of a cross-section of the display panel 100 corresponding to the line X1-X1′ in FIG. 7. FIG. 9 is a cross-sectional view illustrating area A1 of FIG. 8 in detail. FIG. 10 is a cross-sectional view of a display panel corresponding to line X1-X1′ of FIG. 7 according to one or more embodiments.

Each of the plurality of sub-pixels SPX may include an emission area EA (e.g., EA1, EA2 or EA3) that emits light. For example, the first sub-pixel SPX1 may include a first emission area EA1, the second sub-pixel SPX2 may include a second emission area EA2, and the third sub-pixel SPX3 may include a third emission area EA3.

Each emission area EA may include one or more light emitting elements LE that emit light of different wavelengths (e.g., light in different wavelength bands). Here, emission areas that emit light of different wavelengths may include different numbers of light emitting elements depending on the characteristics of the light emitting elements. For example, the first emission area EA1 refers to an area that emits a first light. The first emission area EA1 includes a first-type light emitting element LE1 that emits first light, and the first light may be light in a blue wavelength band. The second emission area EA2 refers to an area that emits a second light. The second emission area EA2 includes a second-type light emitting element LE2 that emits the second light, and the second light may be light in a green wavelength band. The third emission area EA3 refers to an area that emits a third light. The third emission area EA3 includes a third-type light emitting element LE3 that emits the third light and a first-type light emitting element LE1 that emits the first light. The first light output from the first-type light emitting element LE1 in the third emission area EA3 may be converted into the third light and output. The third light may be light in a blue wavelength band. The first-type light emitting element LE1 that emits the first light and the third-type light emitting element LE3 that emits the third light may have different characteristics. For example, the threshold voltage of the third-type light emitting element LE3 may be lower than the threshold voltage of the first-type light emitting element LE1.

Referring to FIGS. 8 and 9 in addition to FIGS. 1-7, the display panel 100 in one or more embodiments may include a substrate SUB, a thin film transistor layer TFTL (also referred to as a “panel circuit layer”) disposed on the substrate SUB, and a light emitting element layer LEL.

The thin film transistor layer TFTL may be located on the substrate SUB and may include a barrier film BR, a plurality of thin film transistors TFT1 and TFT2, a plurality of insulating layers 131, 132, 141, 142, and 133, and a plurality of organic films 160 and 180.

The substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

The barrier film BR may be disposed on the substrate SUB. The barrier film BR may protect the transistors of the thin film transistor layer TFTL and the light emitting element layer LEL from moisture penetrating through the substrate SUB, which may be vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminum oxide layer.

A first thin film transistor TFT1 may be disposed on the barrier film BR. The first thin film transistor TFT1 may be one of the first-type transistors (e.g., P-type transistors) from among the transistors provided to the pixel circuit PXC of each sub-pixel SPX. For example, the first thin film transistor TFT1 may be the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB (or the thickness direction of the display panel 100, for example). The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating film 131 may be disposed on the first channel area CHA1, the first source area S1, and the first drain area D1 of the first thin film transistor TFT1. The first gate insulating film 131 may also be on and may contact exposed portions of the barrier film BR. The first gate insulating film 131 may be formed of an inorganic film, for example, a silicon nitride layer, a silicon oxynitride layer, a silicon oxide layer, a titanium oxide layer, and/or an aluminum oxide layer.

A first gate metal layer may be disposed on the first gate insulating film 131. The first gate metal layer may include the first gate electrode G1 of the first thin film transistor TFT1 and a first capacitor electrode CAE1. The first gate electrode G1 may overlap the first active layer ACT1 in the third direction DR3. In FIG. 8, the first gate electrode G1 and the first capacitor electrode CAE1 are shown to be spaced (e.g., spaced apart or disposed apart) from each other, but the first gate electrode G1 and the first capacitor electrode CAE1 may be connected to each other. The first gate metal layer may be formed as a single layer or multiple layers of molybdenum (Mo), aluminum (Al), chromium (Cr), gold (Au), titanium (Ti), nickel (Ni), neodymium (Nd), and copper (Cu), and/or an alloy thereof.

A second gate insulating film 132 may be disposed on the first gate electrode G1 and the first capacitor electrode CAE1 of the first thin film transistor TFT1. The second gate insulating film 132 may also be on and may contact exposed portions of the first gate insulating film 131. The second gate insulating layer 132 may be formed of an inorganic film, for example, a silicon nitride layer, a silicon oxynitride layer, a silicon oxide layer, a titanium oxide layer, and/or an aluminum oxide layer.

A second gate metal layer may be disposed on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a dielectric constant (e.g., a predetermined dielectric constant), a capacitor (e.g., the capacitor C1 of FIG. 5) may be formed by the first capacitor electrode CAE1, the second capacitor electrode CAE2, and the second gate insulating film 132 disposed between them. The second gate metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

A first interlayer insulating film 141 may be disposed on the second capacitor electrode CAE2. The first interlayer insulating film 141 may also be on and may contact exposed portions of the second gate insulating film 132. The first interlayer insulating layer 141 may be formed of an inorganic film, for example, a silicon nitride layer, a silicon oxynitride layer, a silicon oxide layer, a titanium oxide layer, and/or an aluminum oxide layer.

A second thin film transistor TFT2 may be disposed on the first interlayer insulating film 141. The second thin film transistor TFT2 may be one of the second-type transistors (e.g., N-type transistors) from among the transistors provided to the pixel circuit PXC of each sub-pixel SPX. For example, the second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate insulating film 133 may be disposed on the second active layer ACT2 of the second thin film transistor TFT2. The third gate insulating film 133 may also be on and may contact exposed portions of the first interlayer insulating film 141. The third gate insulating film 133 may be formed of an inorganic film, for example, a silicon nitride layer, a silicon oxynitride layer, a silicon oxide layer, a titanium oxide layer, and/or an aluminum oxide layer.

A third gate metal layer may be disposed on the third gate insulating film 133. The third gate metal layer may include the second gate electrode G2 of the second thin film transistor TFT2. The second gate electrode G2 may overlap the second active layer ACT2 in the third direction DR3. The third gate metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

A second interlayer insulating film 142 may be disposed on the second gate electrode G2 of the second thin film transistor TFT2. The second interlayer insulating film 142 may also be on and may contact exposed portions of the third gate insulating film 133. The second interlayer insulating layer 142 may be formed of an inorganic film, for example, a silicon nitride layer, a silicon oxynitride layer, a silicon oxide layer, a titanium oxide layer, and/or an aluminum oxide layer.

A first data metal layer (which may also be referred to as “first source-drain conductive layer”) may be disposed on the second interlayer insulating film 142. The first data metal layer may include a first source connection electrode PCE1, a second source connection electrode BE1, and a third source connection electrode BE2. The first source connection electrode PCE1 may be connected to the first drain area D1 of the first active layer ACT1 through a first source contact hole PCT1 penetrating the first gate insulating film 131, the second gate insulating film 132, the first interlayer insulating film 141, the third gate insulating film 133, and the second interlayer insulating film 142. A second source connection electrode BE1 may be connected to the second source area S2 of the second active layer ACT2 through the second source connection contact hole BCT1 penetrating the third gate insulating film 133 and the second interlayer insulating film 142. The third source connection electrode BE2 may be connected to the second drain area D2 of the second active layer ACT2 through the third source connection contact hole BCT2 penetrating the third gate insulating film 133 and the second interlayer insulating film 142. The first data metal layer DTL1 may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof. For example, the first data metal layer DTL1 may include a first layer made of titanium (Ti), a second layer made of aluminum (Al), and a third layer made of titanium (Ti).

A first organic layer 160 may be disposed to flatten the step due to the first thin film transistor TFT1 and the second thin film transistor TFT2 on the first source connection electrode PCE1, the second source connection electrode BE1, and the third source connection electrode BE2. The first organic layer 160 may also be on and may contact exposed portions of the second interlayer insulating film 142. The first organic layer 160 may be formed from an organic film such as acrylic resin, epoxy resin, phenolic resin, polyamide resin, polyimide resin, and/or the like.

A second data metal layer may be disposed on the first organic layer 160. The second data metal layer may include a fourth source connection electrode PCE2. The fourth source connection electrode PCE2 may be connected to the first source connection electrode PCE1 through a second pixel contact hole PCT2 penetrating the first organic layer 160. The second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof. For example, the second data metal layer may include a first layer made of titanium (Ti), a second layer made of aluminum (Al), and a third layer made of titanium (Ti).

A second organic layer 180 may be disposed on the fourth source connection electrode PCE2. The second organic layer 180 may be on and may contact exposed portions of the first organic layer 160. The second organic layer 180 may be formed of an organic film such as acrylic resin, epoxy resin, phenolic resin, polyamide resin, polyimide resin, and/or the like.

A light emitting element layer LEL may be disposed on the second organic film 180. The light emitting element layer LEL may include a partition wall BM, pixel electrodes PXE, common electrodes CE, light emitting elements LE, a wavelength conversion layer QDL, a light transmitting layer TPL, and a first capping layer CAP1.

Each emission area EA (e.g., EA1, EA2, or EA3) may be compartmentalized by the partition wall BM. The partition wall BM may be arranged to surround the light emitting element LE. The partition wall BM may be disposed to be spaced (e.g., spaced apart) from the light emitting element LE. The partition wall BM may have a mesh-like, net-like, or lattice-like planar shape. The emission area EA defined by the partition wall BM may have a rectangular planar shape, but embodiments of the present specification are not limited thereto. For example, the emission area EA defined by the partition wall BM may have a polygonal including rectangular, circular, or elliptical planar shape.

The partition wall BM may include a first partition wall BM1 and a second partition wall BM2 that are sequentially stacked. A length of the first partition wall BM1 in the first direction DR1 or the second direction DR2 is greater than a length of the second partition wall BM2 in the first direction DR1 or the second direction DR2. The length (or height) of the first partition wall BM1 in the third direction DR3 (e.g., the thickness direction of the substrate SUB) may be greater than the length (or height) of the second partition wall BM2 in the third direction DR3.

The first partition wall BM1 and the second partition wall BM2 may be formed of an organic film, such as an acrylic resin, an epoxy resin, a phenolic resin, a polyamide resin, a polyimide resin, and/or the like. For example, the first partition wall BM1 and the second partition wall BM2 may include an inorganic black pigment such as carbon black and/or an organic black pigment.

The pixel electrodes PXE (e.g., PXE1, PXE2, PXE3) and the common electrodes CE (e.g., CE1, CE2, CE3) may be disposed on the second organic film 180, which is an area partitioned by the partition wall BM in the light emitting portion EMP (e.g., see FIGS. 4-6). A pixel electrode PXE of each sub-pixel SPX may be connected to a fourth connection electrode PCE2 of the corresponding sub-pixel SPX through a first connection hole (e.g., CT1 in FIG. 7) penetrating the second organic film 180. The common electrode CE of each sub-pixel SPX may be connected to a second power supply line (e.g., VSL in FIG. 5) through a second connection hole (e.g., CT2 in FIG. 7) penetrating the second organic film 180.

In one or more embodiments, the pixel electrode PXE and the common electrode CE of each sub-pixel SPX are non-overlapping with each other in the thickness direction (e.g., third direction DR3) of the light emitting elements LE and may overlap with different portions of the respective light emitting elements LE (e.g., LE1, LE2, LE3). For example, the first pixel electrode PXE1 and the first common electrode CE1 may be non-overlapping with each other in the thickness direction of the first-type light emitting element LE1 of the first sub-pixel SPX1. Further, a portion of the first-type light emitting element LE1 may be disposed on the first pixel electrode PXE1, and another portion of the first-type light emitting element LE1 may be disposed on the first common electrode CE1.

The pixel electrodes PXE and the common electrodes CE may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof. For example, to lower the resistance of each of the pixel electrodes PXE and the common electrodes CE, the pixel electrodes PXE and the common electrodes CE may be formed as a multilayer of copper (Cu) or an alloy of titanium (Ti) and copper (Cu), which has a low surface resistance.

Each light emitting element LE may be disposed on the pixel electrodes PXE and the common electrodes CE. For example, on the respective pixel electrode PXE (e.g., PXE1, PXE2 or PXE3) of each sub-pixel SPX, a portion of the light emitting element LE (e.g., LE1, LE2 or LE3) provided in that sub-pixel (SPX) may be disposed, and on the common electrode CE of each sub-pixel SPX, another portion of the light emitting element LE provided in that sub-pixel SPX may be disposed. In one example, the first contact electrode CTE1 of the light emitting element LE provided in the corresponding sub-pixel SPX may be disposed on the pixel electrode PXE of each sub-pixel SPX, and the second contact electrode CTE2 of the light emitting element LE provided in the corresponding sub-pixel SPX may be disposed on the common electrode CE of each sub-pixel SPX.

In the embodiments of FIGS. 8 and 9, each light emitting element LE may be a flip-type micro-LED. The flip-type micro-LED may refer to an LED in which a first contact electrode CTE1 and a second contact electrode CTE2 are formed on one surface (e.g., the bottom surface) of the light emitting element LE.

In one or more embodiments, each of the light emitting elements LE (e.g., LE1, LE2, and LE3) may be formed of gallium nitride (GaN) or another inorganic material. In one or more embodiments, each of the light emitting elements LE may be a micro light emitting diode having a length in the first direction DR1, a length in the second direction DR2, and a length in the third direction DR3 of several to hundreds of μm, respectively. For example, the length of each of the light emitting elements LE in the first direction DR1, the length in the second direction DR2, and the length in the third direction DR3 may each be 100 μm or less.

Each of the light emitting elements LE may be formed by growing on a semiconductor substrate such as a silicon substrate or sapphire substrate. The light emitting elements LE may be transferred directly from the semiconductor substrate onto the pixel electrodes PXE and the common electrodes CE of the display panel 100. Alternatively, the light emitting elements LE may be transferred to the pixel electrodes PXE and common electrodes CE of the display panel 100 by electrostatic method using an electrostatic head or by stamping method using an elastic polymeric material such as polydimethylsiloxane (PDMS) or silicone as a transfer substrate.

Each of the light emitting elements LE may include a first semiconductor layer SEM1, an emission layer EML, a second semiconductor layer SEM2, and a protective film INS. In one or more embodiments, each of the light emitting elements LE may further include at least one contact electrode. For example, each of the light emitting elements LE may further include a first contact electrode CTE1 connected to the first semiconductor layer SEM1, and a second contact electrode CTE2 connected to the second semiconductor layer SEM2.

The first contact electrode CTE1 may be disposed on the pixel electrode PXE of each sub-pixel SPX. For example, the first contact electrode CTE1 may be disposed between the pixel electrode PXE of the respective sub-pixel SPX and the first semiconductor layer SEM1 of the light emitting element LE. The first contact electrode CTE1 may connect the first semiconductor layer SEM1 of the light emitting element LE to the pixel electrode PXE of the respective sub-pixel SPX.

The second contact electrode CTE2 may be disposed on the common electrode CE of each sub-pixel SPX. For example, the second contact electrode CTE2 may be disposed between the common electrode CE of the respective sub-pixel SPX and the second semiconductor layer SEM2 of the light emitting element LE. The second contact electrode CTE2 may connect the second semiconductor layer SEM2 of the light emitting element LE to the common electrode CE of the respective sub-pixel SPX.

The first contact electrode CTE1 and the second contact electrode CTE2 may include a metal, a metal oxide, and/or other suitable conductive material. In one example, the first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the first contact electrode CTE1. In one or more embodiments, the first semiconductor layer SEM1 may be made of GaN doped with a first conductivity type dopant (e.g., P-type dopant) such as Mg, Zn, Ca, Se, Ba, and/or the like.

The first semiconductor layer SEM1 may be electrically connected to the pixel electrode PXE of the respective sub-pixel SPX. For example, the first semiconductor layer SEM1 may be electrically connected to the pixel electrode PXE of the respective sub-pixel SPX through the first contact electrode CTE1.

The emission layer EML may be disposed on the first semiconductor layer SEM1. For example, the emission layer EML may be disposed between the first semiconductor layer SEM1 and the second semiconductor layer SEM2. The emission layer EML may emit light by recombination of electron-hole pairs according to an electrical signal applied through the first semiconductor layer SEM1 and the second semiconductor layer SEM2.

The emission layer EML may include a material having a single or multi-quantum well structure. When the emission layer EML includes a material having a multi-quantum well structure, it may have a structure in which a plurality of well layers and barrier layers are alternately stacked. In one or more embodiments, the well layer may be formed of InGaN, and the barrier layer may be formed of GaN and/or AlGaN but is not limited thereto. Alternatively, the emission layer EML may have a structure in which semiconductor materials having a high band gap energy and semiconductor materials having a low band gap energy are alternately stacked with each other, may include other Group Ill to V semiconductor materials according to the wavelength range of emitted light.

When the emission layer EML includes InGaN, the color of the emitted light may vary depending on the content of indium (In). For example, as the content of indium (In) increases, the wavelength band of light emitted by the emission layer EML may shift to the red wavelength band, and as the content of indium (In) decreases, the wavelength band of light emitted by the emission layer EML may shift to the blue wavelength band. For example, the content of indium (In) in the emission layer EML of the light emitting element LE that emits the third light (e.g., light in the blue wavelength band) may be approximately 10 wt % to 20 wt %.

The second semiconductor layer SEM2 may be disposed on the emission layer EML. In one or more embodiments, the second semiconductor layer SEM2 may be N—GaN doped with a second conductive dopant (e.g., an N-type dopant) such as Si, Ge, Sn, and/or the like.

The second semiconductor layer SEM2 may be electrically connected to the common electrode CE of each sub-pixel SPX. For example, the second semiconductor layer SEM2 may be electrically connected to the common electrode CE of respective sub-pixel SPX through the second contact electrode CTE2.

In one or more embodiments, the second semiconductor layer SEM2 may have a larger area than the first semiconductor layer SEM1 and the emission layer EML. The second semiconductor layer SEM2 may include a first portion SEM21 overlapping the first semiconductor layer SEM1 and the emission layer EML, and a second portion SEM22 and a third portion SEM23 extending from the first portion SEM21 and non-overlapping the first semiconductor layer SEM1 and the emission layer EML.

The second portion SEM22 of the second semiconductor layer SEM2 may be disposed on the second contact electrode CTE2. The second contact electrode CTE2 may be disposed between the second portion SEM22 of the second semiconductor layer SEM2 and the respective common electrode CE.

In one or more embodiments, the second portion SEM22 of the second semiconductor layer SEM2 may have a greater thickness than the remaining portion of the second semiconductor layer SEM2. Accordingly, the light emitting element LE may be stably disposed or connected to each pixel electrode PXE and the common electrode CE without increasing the thickness of the second contact electrode CTE2. In one or more other embodiments, the second portion SEM22 of the second semiconductor layer SEM2 may have a thickness similar to the remaining portion of the second semiconductor layer SEM2, and the second contact electrode CTE2 may have a thickness greater than the first contact electrode CTE1. Accordingly, the light emitting element LE may be stably disposed or connected on the respective pixel electrode PXE and the common electrode CE.

The third portion SEM23 of the second semiconductor layer SEM2 may connect the first portion SEM21 and the second portion SEM22 of the second semiconductor layer SEM2. In one or more embodiments, the third portion SEM23 of the second semiconductor layer SEM2 may have a thickness smaller than the remaining portions of the second semiconductor layer SEM2, but the present disclosure is not limited thereto.

The protective film INS may cover the first semiconductor layer SEM1, the emission layer EML, and the second semiconductor layer SEM2. For example, the protective film INS may cover the outer surfaces (e.g., outer peripheral or circumferential surfaces) of the first semiconductor layer SEM1, the emission layer EML, and the second semiconductor layer SEM2.

The protective film INS may be a film to protect the side surface of the light emitting element LE. The protective film INS may be formed of an inorganic film, for example, a silicon nitride layer, a silicon oxynitride layer, a silicon oxide layer, a titanium oxide layer, and/or an aluminum oxide layer.

A wavelength conversion layer QDL or a light transmitting layer TPL may be disposed in an area partitioned by the partition wall BM of the light emitting portion EMP. For example, the first emission area EA1 and the second emission area EA2 may include a light transmitting layer TPL, and the third emission area EA3 may include a wavelength conversion layer QDL.

The wavelength conversion layer QDL and the light transmitting layer TPL may be disposed to contact the pixel electrode PXE, the common electrode CE, the light emitting element LE, etc. The wavelength conversion layer QDL and the light transmitting layer TPL may be disposed to substantially cover the members including the light emitting element LE. For example, the wavelength conversion layer QDL and the light transmitting layer TPL may be arranged to surround the side and/or top surfaces of the light emitting element LE.

Meanwhile, the light transmitting layer TPL may include a light-transmitting organic material. For example, the light transmitting layer TPL may include an epoxy-based resin, an acrylic-based resin, a cardo-based resin, an imide-based resin, and/or the like.

However, the embodiments of the present disclosure are not limited to this, and the first wavelength conversion layer may be disposed in the first emission area EA1 instead of the light transmitting layer TPL, and the second emission area EA2 may have a second wavelength conversion layer instead of the light transmitting layer TPL. The first wavelength conversion layer may include quantum dots (QD), quantum rods, fluorescent materials, and/or phosphorescent materials that convert light other than light in the blue wavelength band to (or into) the light in the blue wavelength band, and the second wavelength conversion layer may include quantum dots (QD), quantum rods, fluorescent materials, and/or phosphorescent materials that convert light other than light in the green wavelength band to (or into) light in the green wavelength band. Additionally, the first wavelength conversion layer and the second wavelength conversion layer may include quantum dots as well as a light diffusion agent such as titanium dioxide (TiO₂). In this case, the number of titanium dioxide (TiO₂) particles in the first wavelength conversion layer and/or the number of titanium dioxide (TiO₂) particles in the second wavelength conversion layer may be greater than the number of titanium dioxide (TiO₂) particles in the wavelength conversion layer QDL. In this way, when the wavelength conversion layer is disposed in the first emission area EA1 and the second emission area EA2 instead of the light transmitting layer TPL, the color purity of the light from the first emission area EA1 and the second emission area EA2 may be increased.

The wavelength conversion layer QDL of the third emission area EA may include a wavelength conversion material that converts light in the blue wavelength band emitted from the first-type light emitting element LE1 to (or into) light in the red wavelength band. By way of example, the wavelength conversion layer QDL may include wavelength conversion particles (or the wavelength conversion material) WCP and base resin BRS. The wavelength conversion material may include quantum dots (QD), quantum rods, a fluorescent material, and/or a phosphorescent material. Additionally, the wavelength conversion layer QDL may include a light diffusion agent such as titanium dioxide (TiO₂) in addition to quantum dots. In this case, the number of titanium dioxide (TiO₂) particles in the first wavelength conversion layer and/or the number of titanium dioxide (TiO₂) particles in the second wavelength conversion layer may be greater than the number of titanium dioxide (TiO₂) particles in the wavelength conversion layer QDL. In this way, the third emission area EA3 may emit light in a red wavelength band (e.g., light of a red wavelength).

The first capping layer CAP1 may be disposed on the side and top surfaces of the partition wall BM. That is, the first capping layer CAP1 may be disposed on the side of the first partition wall BM1 and the side and top surfaces of the second partition wall BM2. The first capping layer CAP1 may be disposed to surround the top, bottom, and/or side(s) of the wavelength conversion layer QDL, as it serves to protect the wavelength conversion particles WCP of the wavelength conversion layer QDL and the wavelength conversion particles WCP2 of the wavelength conversion layer QDL from moisture penetration. Also, it may be disposed to surround the top, bottom, and/or side(s) of the light transmitting layer TPL.

The reflective layer RF may be disposed between the partition wall BM and the light transmitting layer TPL, and/or between the partition wall BM and the wavelength conversion layer QDL. The reflective layer RF may be disposed on a first capping layer CAP1 disposed on the side of the first partition wall BM1 and the side of the second partition wall BM2. The reflective layer RF may serve to reflect light traveling in the lateral direction from the wavelength conversion layer QDL and the light transmitting layer TPL.

The reflective layer RF may include a highly reflective metal material such as aluminum (Al). In one or more embodiments, the thickness of the reflective layer RF may be approximately 0.1 μm.

Alternatively, the reflective layer RF may include M pairs of first and second layers with different refractive indices, where M is an integer greater than or equal to 2, to act as Distributed Bragg Reflectors (DBR). In this case, M first layers and M second layers may be arranged alternately. The first layer and the second layer may be formed of an inorganic film, for example, a silicon nitride layer, a silicon oxynitride layer, a silicon oxide layer, a titanium oxide layer, and/or an aluminum oxide layer.

The second capping layer CAP2 may be disposed on the first capping layer CAP1, the light transmitting layer TPL, and the wavelength conversion layer QDL. The second capping layer CAP2 may be formed of an inorganic film, for example, a silicon nitride layer, a silicon oxynitride layer, a silicon oxide layer, a titanium oxide layer, and/or an aluminum oxide layer. The light transmitting layer TPL and the wavelength conversion layer QDL may be encapsulated by the first capping layer CAP1 and/or the second capping layer CAP2.

A third organic film 193 may be disposed on the second capping layer CAP2. The third organic film 193 may be formed from an acrylic resin, an epoxy resin, a phenolic resin, a polyamide resin, a polyimide resin, and/or the like.

Color filters may be disposed on the third organic film 193. The color filters may include a first color filter CF1, a second color filter CF2, and a third color filter CF3.

The first color filter CF1 may be disposed in the first sub-pixel SPX1. The first color filter CF1 may transmit the first light (e.g., light in a blue wavelength band). For example, the first color filter CF1 may transmit the first light emitted from the first-type light emitting element LE1 and passing through the light transmitting layer TPL. Accordingly, the first sub-pixel SPX1 may emit the first light.

The second color filter CF2 may be disposed in the second sub-pixel SPX2. The second color filter CF2 may transmit the second light (e.g., light in a green wavelength band). For example, the second color filter CF2 may transmit the second light emitted from the second-type light emitting element LE2 and passing through the light transmitting layer TPL. Accordingly, the second sub-pixel SPX2 may emit the second light.

The third color filter CF3 may be disposed in the third sub-pixel SPX3. The third color filter CF3 may transmit the third light (for example, light in a red wavelength band) and absorb or block the first light. For example, the third color filter CF3 may transmit the third light converted by the wavelength conversion layer QDL from among the first light emitted by the first-type light emitting element LE1 and transmit the third light emitted by the third-type light emitting element LE3. Accordingly, the third sub-pixel SPX3 may emit the third light.

The first color filter CF1, the second color filter CF2, and the third color filter CF3 may overlap the partition wall BM in the third direction DR3.

A fourth organic film 194 for planarization may be disposed on the first, second, and third color filters CF1, CF2, and CF3. The fourth organic film 194 may be formed from an acrylic resin, an epoxy resin, a phenolic resin, a polyamide resin, a polyimide resin, and/or the like.

Referring to FIG. 10, the second sub-pixel SPX2 is different from the embodiment of FIG. 8 in that it includes a first-type light emitting element LE1 and a second wavelength conversion layer QDL2.

The first-type light emitting element LE1 emits first light in the blue wavelength band.

The second wavelength conversion layer QDL2 may include a base resin BRS and second wavelength conversion particles WCP2. The base resin BRS may include a light-transmitting organic material. For example, the base resin BRS may include an epoxy-based resin, an acrylic-based resin, a cardo-based resin, or an imide-based resin. The second wavelength conversion particle WCP2 may convert a portion of the first light (e.g., light in the blue wavelength band) incident from the light emitting element LE to (or into) second light (e.g., light in the green wavelength band). The second wavelength conversion particle WCP2 may be a quantum dot (QD), a quantum rod, a fluorescent material, or a phosphorescent material. The second light conversion layer QDL2 may further include a light diffusion agent such as titanium dioxide (TiO₂).

In one or more embodiments, the wavelength conversion particles of the second wavelength conversion layer QDL2 of the second sub-pixel SPX2 and/or the wavelength conversion layer QDL3 of the third sub-pixel SPX3 may be yellow phosphors that convert absorbed light to (or into) light in a yellow wavelength band (e.g., light of yellow wavelengths). When the wavelength conversion particles WCP2 of the second wavelength conversion layer QDL2 of the second sub-pixel SPX2 include yellow phosphor, only green light may be transmitted through the green color filter. Also, when the wavelength conversion particles WCP3 of the wavelength conversion layer QDL3 of the third sub-pixel SPX3 include yellow phosphor, only red light may be transmitted through the red color filter.

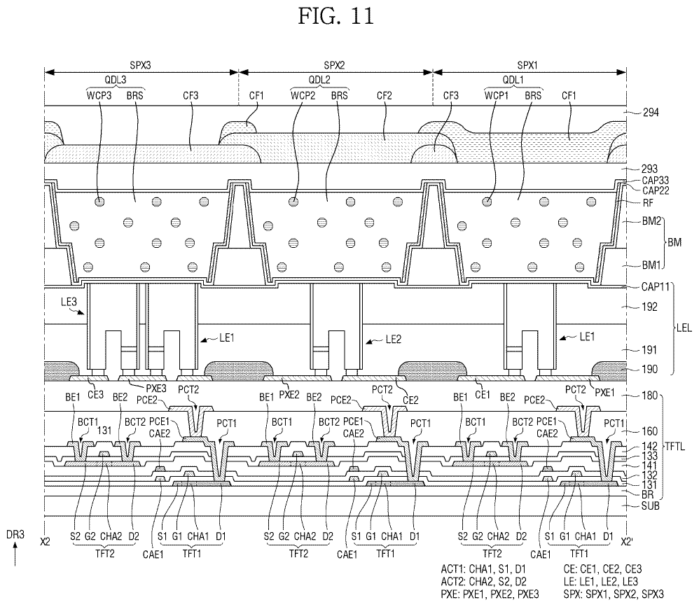

FIG. 11 is a cross-sectional view illustrating sub-pixels according to one or more embodiments of the present disclosure. For example, FIG. 11 illustrates another embodiment of a cross section of the display panel 100 corresponding to line X1-X1′ in FIG. 7.

FIG. 11 is different from FIG. 10 in that the wavelength conversion layer QDL is not arranged to surround the light emitting element LE. Additionally, the bank 190 may be disposed on the second organic film 180.

Referring to FIG. 10 in addition to FIGS. 1-7, the pixel electrodes PXE (e.g., PXE1, PXE2, PXE3), the common electrodes CE (CE1, CE2, CE3), and the bank 190 may be disposed in direct contact with the second organic film 180.

The pixel electrode PXE and the common electrode CE may be disposed on the second organic film 180 to be spaced (e.g., spaced apart) from each other, and the bank 190 may cover a portion of each of the pixel electrodes PXE and common electrodes CE. For example, the bank 190 may cover at least one edge of the pixel electrodes PXE and the common electrodes CE. The bank 190 may not be disposed on the remaining portions of the pixel electrodes PXE and the common electrodes CE. For example, the bank 190 may not be disposed on the center portion of each of the pixel electrodes PXE and common electrodes CE, and on the edges of the pixel electrodes PXE and common electrodes CE where the pixel electrodes PXE and common electrodes CE face each other.

The bank 190 may be formed of an organic film such as an acrylic resin, epoxy resin, phenolic resin, polyamide resin, polyimide resin, and/or the like. The bank 190 may include a light blocking material to prevent light from the light emitting element LE of one sub-pixel SPX from proceeding to the neighboring sub-pixel SPX. For example, the bank 190 may include an inorganic black pigment such as carbon black and/or an organic black pigment.

Each light emitting element LE may be disposed on the pixel electrodes PXE and the common electrodes CE.

A third organic film 191 and a fourth organic film 192 may be disposed around the light emitting elements LE. For example, the third organic film 191 may be disposed on at least a portion of the bank 190, the pixel electrodes PXE, and the common electrodes CE, and the fourth organic film 192 may be disposed on the third organic film 191. The third organic film 191 and the fourth organic film 192 may cover the side surfaces of the light emitting elements LE. Each of the third organic film 191 and the fourth organic film 192 may be formed from an organic film such as an acrylic resin, an epoxy resin, a phenolic resin, a polyamide resin, a polyimide resin, and/or the like.

The third organic film 191 and the fourth organic film 192 may be layers for flattening steps caused by the light emitting elements LE. When the height of the third organic film 191 is arranged to cover most of the side surfaces of each light emitting element LE, the fourth organic film 192 may be omitted.

A first capping layer CAP11 may be disposed on the light emitting elements LE and the fourth organic film 192. The first capping layer CAP11 may be formed of an inorganic film, for example, a silicon nitride layer, a silicon oxynitride layer, a silicon oxide layer, a titanium oxide layer, and/or an aluminum oxide layer.

The partition wall BM and wavelength conversion layers QDL1, QDL2, and QDL3 may be disposed on the first capping layer CAP11. The wavelength conversion layer QDL1, QDL2, or QDL3 may be formed in respective light emitting area compartmentalized by the partition wall BM. For example, the first sub-pixel SPX1 may have the partition wall BM and the first wavelength conversion layer QDL1 disposed on the first capping layer CAP11, the second sub-pixel SPX2 may have the partition wall BM and the second wavelength conversion layer QDL2 disposed on the first capping layer CAP11, and the third sub-pixel SPX3 may have the partition wall BM and the third wavelength conversion layer QDL3 disposed on the first capping layer CAP11. However, the embodiments of the present disclosure are not limited to this, and the first sub-pixel SPX1 and the second sub-pixel SPX2 may have a light transmitting layer TPL instead of the wavelength conversion layers QDL1 and QDL2.

The first wavelength conversion layer QDL1 may include a base resin BRS and first wavelength conversion particles WCP1. The first wavelength conversion particles WCP1 may convert light other than light in the blue wavelength band to (or into) first light in the blue wavelength band. The first wavelength conversion particles WCP1 may be quantum dots (QD), quantum rods, a fluorescent material, and/or a phosphorescent material. When the first wavelength conversion particles WCP1 include quantum dots (QD) and/or quantum rods, the first wavelength conversion layer QDL1 may further include a light diffusion agent such as titanium dioxide (TiO₂) particles.

The second wavelength conversion layer QDL2 may include a base resin BRS and second wavelength conversion particles WCP2. The second wavelength conversion particles WCP2 may convert light other than light in the green wavelength band to (or into) second light in the green wavelength band. The second wavelength conversion particles WCP2 may be quantum dots (QD), quantum rods, a fluorescent material, and/or a phosphorescent material. When the second wavelength conversion particles WCP2 include quantum dots (QD) and/or quantum rods, the second wavelength conversion layer QDL2 may further include a light diffusion agent such as titanium dioxide (TiO₂) particles.

The third wavelength conversion layer QDL3 may include a base resin BRS and third wavelength conversion particles WCP3. The third wavelength conversion particles WCP3 may convert light other than light in the red wavelength band to (or into) second light in the red wavelength band. The third wavelength conversion particles WCP3 may be quantum dots (QD), quantum rods, a fluorescent material, or a phosphorescent material. When the third wavelength conversion particles WCP3 include quantum dots (QD) and/or quantum rods, the third wavelength conversion layer QDL3 may further include a light diffusion agent such as titanium dioxide (TiO₂) particles. In one or more embodiments, the first sub-pixel SPX1 and the second sub-pixel SPX2 may be arranged with a light-transmitting layer instead of the wavelength conversion layers QDL1 and QDL2.

The partition wall BM may overlap the bank 190 in the third direction DR3 and may not overlap the light emitting elements LE.

A second capping layer CAP22 may be disposed on the first capping layer CAP11 and the partition wall BM. The second capping layer CAP22 may be disposed on the side and top surfaces of the partition wall BM. That is, the second capping layer CAP22 may be disposed on the side of the first partition wall BM1 and/or the side and top surfaces of the second partition wall BM2. The second capping layer CAP22 may serve to protect the wavelength conversion particles WCP (e.g., WCP1, WCP2, WCP3) of the wavelength conversion layer QDL (e.g., QDL1, QDL2, QDL3) from moisture penetration, and thus may be disposed to surround the top, bottom, and/or side(s) of the wavelength conversion layer QDL.

A third capping layer CAP33 may be disposed on the second capping layer CAP22, the light transmitting layer TPL, and the wavelength conversion layer QDL. The refractive index of the third capping layer CAP33 may be lower than the refractive index of the second capping layer CAP22. Further, the refractive index of the third capping layer CAP33 may be lower than the refractive index of the fifth organic film 293.

A fifth organic film 293 may be disposed on the second capping layer CAP22.

Color filters CF1, CF2 and CF3 may be disposed on the fifth organic film 293. A sixth organic film 294 for planarization may be disposed on the color filters.

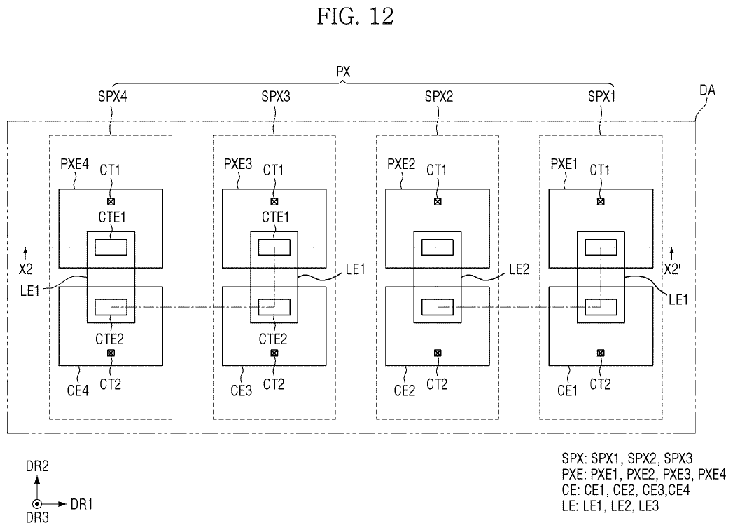

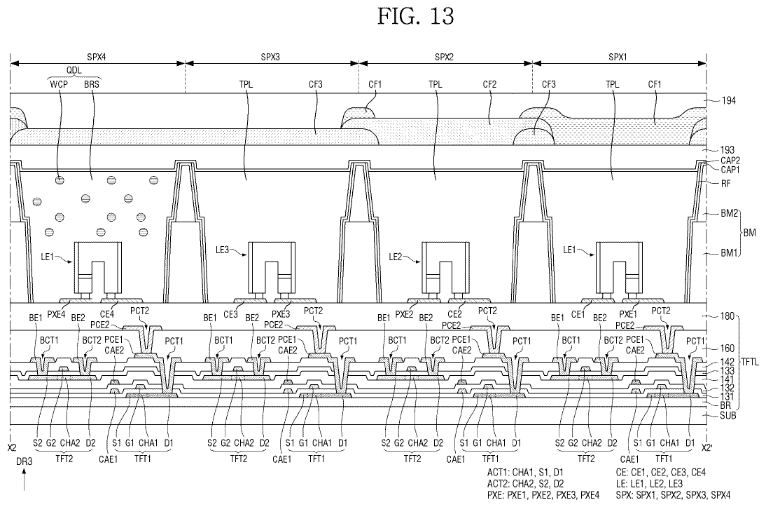

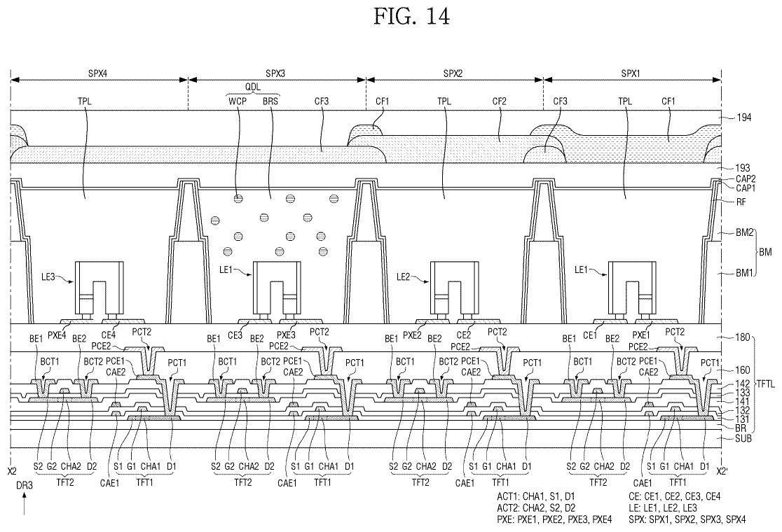

FIG. 12 is a plan view illustrating sub-pixels according to one or more embodiments. FIG. 13 is a cross-sectional view illustrating a display panel 100 according to one or more embodiments. For example, FIG. 13 illustrates one example of a cross section of the display panel corresponding to the lines X2-X2′ in FIG. 12. FIG. 14 is a cross-sectional view of a display panel 100 corresponding to the X2-X2′ lines in FIG. 12 according to one or more other embodiments.

FIG. 12 differs from the embodiments of FIGS. 7-10 in that a first sub-pixel SPX1, a second sub-pixel SPX2, a third sub-pixel SPX3, and a fourth sub-pixel SPX4 constituting the pixel have the same number of light emitting elements. When three or more sub-pixels constitute one pixel, the light emitting elements LE may be InGaN-based elements.

FIG. 12 illustrates one or more embodiments in which one unit pixel PX includes the first sub-pixel SPX1, the second sub-pixel SPX2, the third sub-pixel SPX3, and the fourth sub-pixel SPX4.

In FIGS. 12 and 13, the first sub-pixel SPX1 may emit a first light, the second sub-pixel SPX2 may emit a second light, and the third sub-pixel SPX3 and the fourth sub-pixel SPX4 may emit a third light. In one or more embodiments, the first light may be light in a blue wavelength band, the second light may be light in a green wavelength band, and the third light may be light in a red wavelength band. In one example, the first light, the second light, and the third light may be a blue light having a peak wavelength ranging from approximately 440 nm to 480 nm, a green light having a peak wavelength ranging from approximately 510 nm to 550 nm, and a red light having a peak wavelength ranging from approximately 610 nm to 650 nm, respectively. The color or wavelength band of light emitted from each sub-pixel SPX may vary depending on embodiments.

As shown in FIGS. 12 and 13, sub-pixels SPX (e.g., SPX1, SPX2, SPX3, SPX4) may each include a pixel electrode PXE (e.g., PXE1, PXE2, PXE3, or PXE4), a common electrode CE (e.g., CE1, CE2, CE3, or CE4), a light emitting element LE (e.g., LE1, LE2, LE3, or LE4), and either a wavelength conversion layer QDL or a light transmitting layer TPL. For example, the first sub-pixel SPX1 may include a first pixel electrode PXE1, a first common electrode CE1, a first-type light emitting element LE1, and a light transmitting layer TPL. The first-type light emitting element LE1 may emit a first light in a blue wavelength band. The light transmitting layer TPL may transmit the first light. Accordingly, the first sub-pixel SPX1 may emit the first light in the blue wavelength band.

The second sub-pixel SPX2 may include a second pixel electrode PXE2, a second common electrode CE2, a second-type light emitting element LE2, and a light transmitting layer TPL. The second-type light emitting element LE2 may emit a second light in a green wavelength band. The light transmitting layer TPL may transmit the second light. Accordingly, the second sub-pixel SPX2 may emit the second light in the green wavelength band.

The third sub-pixel SPX3 may include a third pixel electrode PXE3, a third common electrode CE3, a third-type light emitting element LE3, and a light transmitting layer TPL. The third-type light emitting element LE3 may emit a third light in a red wavelength band. The light transmitting layer TPL may transmit the third light. Accordingly, the third sub-pixel SPX3 may emit the third light in the red wavelength band.

The fourth sub-pixel SPX4 may include a fourth pixel electrode PXE4, a fourth common electrode CE4, a first-type light emitting element LE1, and a wavelength conversion layer QDL. The first-type light emitting element LE1 may emit a first light in a blue wavelength band. The wavelength conversion layer QDL may include a base resin BRS and wavelength conversion particles WCP that convert light in the blue wavelength band emitted from the first-type light emitting element LE1 to (or into) light in a red wavelength band. The wavelength conversion particles WCP may be quantum dots (QD), quantum rods, a fluorescent material, and/or a phosphorescent material. Additionally, the wavelength conversion layer QDL may include a light diffusion agent such as titanium dioxide (TiO₂) particles in addition to quantum dots and/or quantum rods. Accordingly, the fourth sub-pixel SPX4, like the third sub-pixel SPX3, may emit third light in the red wavelength band.

The threshold voltage of the first-type light emitting element LE1 and the threshold voltage of the third-type light emitting element LE3 may be different from each other. Therefore, when a low driving current in the low-gray level range is applied, the third-type light emitting element LE emits light in a curve corresponding to each gray level, and when a high driving current in the high-gray level range is applied, the third-type light emitting element LE3 as well as the first light emitting element LE1, which has a relatively high luminous efficiency, are emitted, so that the driving current may be appropriately limited. Accordingly, the sub-pixel SPX may be appropriately emitted with high brightness corresponding to each gradation (or gray level) while reducing or improving power consumption.

Referring to FIG. 14, the third sub-pixel SPX3 may differ from the one or more embodiments of FIG. 13 in that the third sub-pixel SPX3 includes a first-type light emitting element LE1 and the fourth sub-pixel SPX4 includes a third-type light emitting element LE3.

Referring to FIG. 14, the third sub-pixel SPX3 may include a third pixel electrode PXE3, a third common electrode CE3, a first-type light emitting element LE1, and a wavelength conversion layer QDL. The first-type light emitting element LE1 may emit a first light in a blue wavelength band. The wavelength conversion layer QDL may include a base resin BRS and wavelength conversion particles WCP that convert light in the blue wavelength band emitted from the first-type light emitting element LE1 to (or into) light in a red wavelength band. Accordingly, the third sub-pixel SPX3 may emit light in the red wavelength band.

The fourth sub-pixel SPX4 may include a fourth pixel electrode PXE3, a fourth common electrode CE4, a third-type light emitting element LE3, and a light transmitting layer TPL. The third-type light emitting element LE3 may emit a third light in the red wavelength band. The light transmitting layer TPL may transmit the third light. Accordingly, the fourth sub-pixel SPX4 may emit the third light in the red wavelength band.

Referring to FIGS. 13 and 14, a pixel may include a plurality of sub-pixels having one light emitting element and may include a structure in which a first sub-pixel SPX1 including a first-type light emitting element LE1, a second sub-pixel SPX2 including a second-type light emitting element LE2, a third sub-pixel SPX3 including a third-type light emitting element LE3, and a fourth sub-pixel SPX4 including a first-type light emitting element LE1 and a wavelength conversion layer QDL is listed in order, or a structure in which a first sub-pixel SPX1 including a first-type light emitting element LE1, a second sub-pixel SPX2 including a second-type light emitting element LE2, a third sub-pixel SPX3 including a first-type light emitting element LE1 and a wavelength conversion layer QDL, and a fourth sub-pixel SPX4 including a third-type light emitting element LE3 is listed in order.

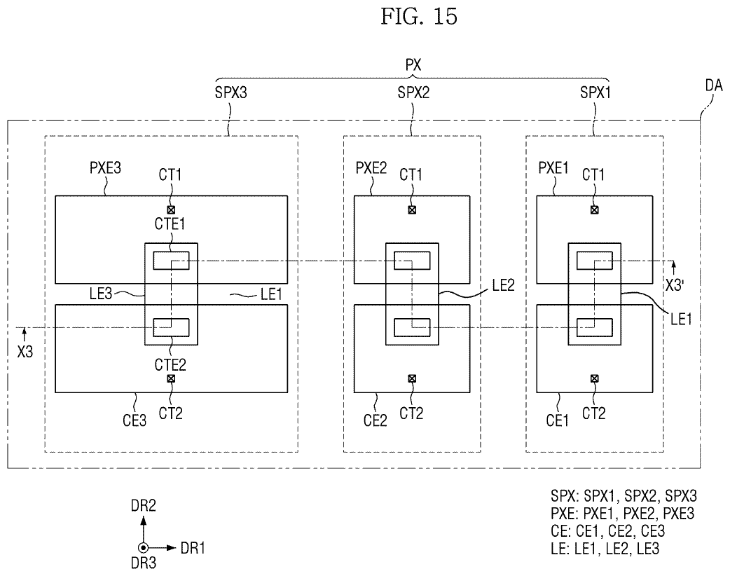

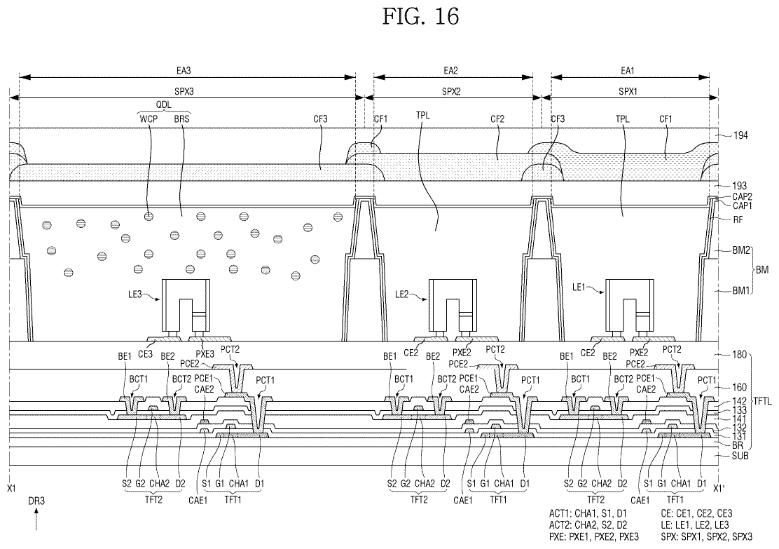

FIG. 15 is a plan view illustrating sub-pixels according to one or more embodiments. FIG. 16 is a cross-sectional view illustrating a display panel according to one or more embodiments. For example, FIG. 16 illustrates one example of a cross section of the display panel 100 corresponding to the line X3-X3′ in FIG. 15.

The display panels of FIGS. 15 and 16 differ from the display panels illustrated in FIGS. 7 and 8 in that the sub-pixels SPX included in the pixels have different sizes, and the number of light emitting elements LE included in each sub-pixel SPX is the same.

For example, the size of the third sub-pixel SPX3 including the third-type light emitting element LE3 for emitting light in a red wavelength band (e.g., light of a red wavelength) may be larger than the size of the first sub-pixel SPX1 including the first-type light emitting element LE1 for emitting light in a blue wavelength band (e.g., light of a blue wavelength) and the size of the second sub-pixel SPX2 including the second-type light emitting element LE2 for emitting light in a green wavelength band (e.g., light of a green wavelength). The size of the third sub-pixel SPX3 may be more than twice the size of the first sub-pixel SPX1 and the size of the second sub-pixel SPX2.

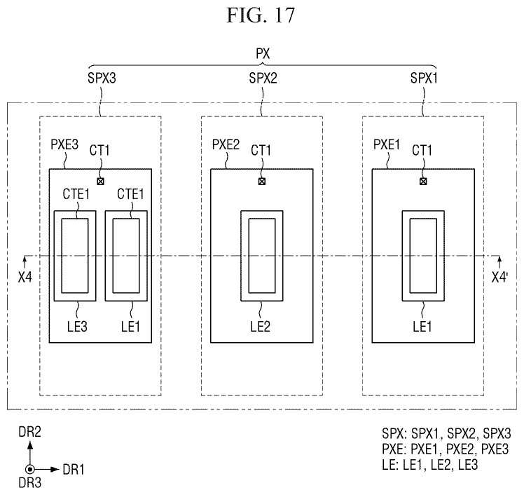

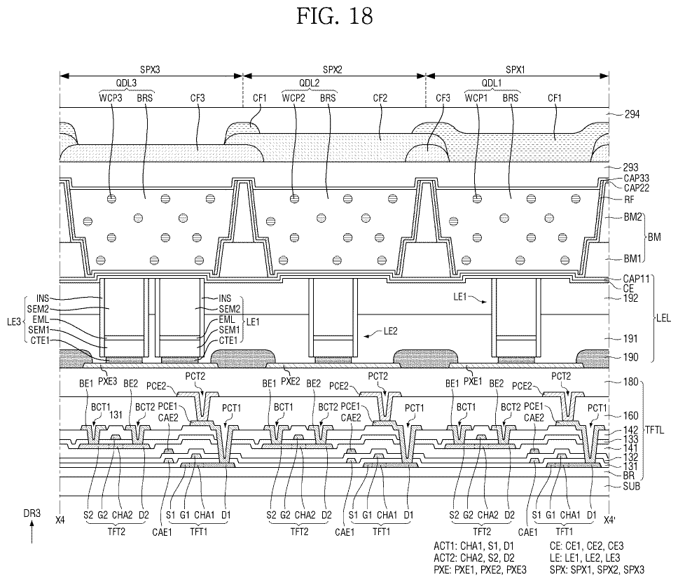

FIG. 17 is a plan view illustrating sub-pixels according to one or more embodiments. FIG. 18 is a cross-sectional view illustrating a display panel according to one or more embodiments. For example, FIG. 18 illustrates one example of a cross section of the display panel 100 corresponding to the line X4-X4′ in FIG. 17. FIGS. 17 and 18 illustrate an embodiment that differ from the embodiments of FIGS. 7-9 with respect to the pixel electrodes PXE, the common electrode CE, and the light emitting elements LE.

Referring to FIGS. 17 and 18 in addition to FIGS. 1-9, the pixel electrode PXE (e.g., PXE1, PXE2, PXE3) and the common electrode CE of each sub-pixel SPX (e.g., SPX1, SPX2, SPX3) may overlap each other. For example, the pixel electrode PXE and the common electrode CE may overlap each other in the thickness direction of the light emitting elements LE (e.g., the third direction DR3). In one or more embodiments, the pixel electrode PXE may be formed individually for each sub-pixel SPX, and the common electrode CE may be formed as an electrode shared by a plurality of sub-pixels SPX. For example, the first common electrode CE1, the second common electrode CE2, and the third common electrode CE3 shown in FIGS. 7-16 may be integrated into one common electrode CE. The edges of each of the pixel electrodes PXE may be covered by the bank 190.

The light emitting elements LE of each sub-pixel SPX may be disposed between the pixel electrode PXE (e.g., PXE1, PXE2, or PXE3) of the corresponding sub-pixel SPX and the common electrode CE. For example, the light emitting element or elements LE (LE1, LE2 and/or LE3) of each sub-pixel SPX may be disposed on the pixel electrode PXE of the corresponding sub-pixel SPX and may be covered with the common electrode CE. In one example, the first-type light emitting element LE1 of the first sub-pixel SPX1 may be disposed on the first pixel electrode PXE1, and the second-type light emitting element LE2 of the second sub-pixel SPX2 may be disposed on the second pixel electrode PXE2. The first-type light emitting element LE1 and the third-type light emitting element LE3 of the third sub-pixel SPX3 may be disposed on the third pixel electrode PXE3.

Each of the light emitting elements LE may include a first semiconductor layer SEM1, an emission layer EML, and a second semiconductor layer SEM2 sequentially disposed along the third direction DR3. For example, each of the light emitting elements LE may be a vertical type micro LED extending in the third direction DR3. A vertical micro LED may refer to an LED having a structure in which the first semiconductor layer SEM1, the emission layer EML, and the second semiconductor layer SEM2 are sequentially arranged in the vertical third direction DR3.

In one or more embodiments, the first semiconductor layer SEM1, the emission layer EML, and the second semiconductor layer SEM2 of each of the light emitting elements LE may have substantially the same or similar areas but the present disclosure is not limited thereto.

Each of the light emitting elements LE may further include a protective film INS. The protective film INS may cover the sides of the first semiconductor layer SEM1, the emission layer EML, and/or the second semiconductor layer SEM2.

In one or more embodiments, each of the light emitting elements LE may include a first contact electrode CTE1 connected to the respective pixel electrode PXE (e.g., PXE1, PXE2 or PXE3). The first semiconductor layer SEM1, the emission layer EML, and the second semiconductor layer SEM2 of each of the light emitting elements LE may be sequentially disposed on the first contact electrode CTE1.

In one or more embodiments, each of the light emitting elements LE may not include the second contact electrode CTE2 described in the previously described embodiments. For example, the second semiconductor layer SEM2 may be directly connected to the common electrode CE.

In one or more embodiments, the common electrode CE may be entirely disposed on the light emitting elements LE of the sub-pixels SPX. As one example, the common electrode CE may be disposed on the light emitting elements LE of the sub-pixels SPX and the fourth organic film 192 disposed in the display area DA, and may be formed entirely in the display area DA. In one or more embodiments, the common electrode CE may be disposed directly on the second semiconductor layers SEM2 of the light emitting elements LE.

The common electrode CE may be made of a transparent conductive material (TCO), such as indium tin oxide (ITO) and/or indium zinc oxide (IZO), which may transmit light. The common electrode CE may be covered with the first capping layer CAP11.

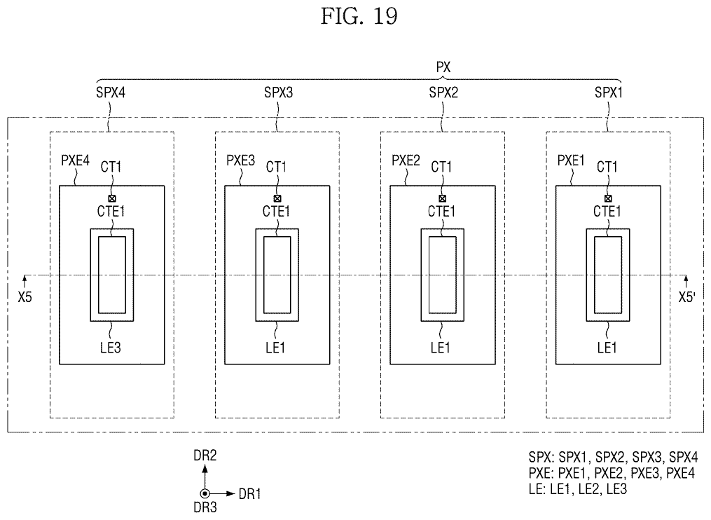

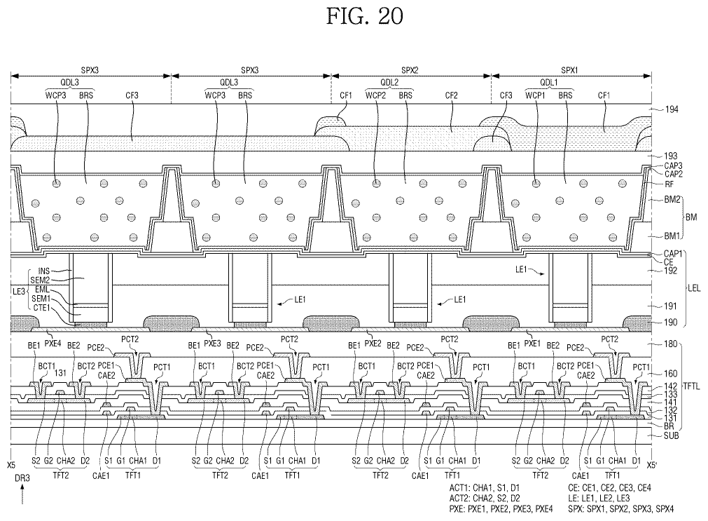

FIG. 19 is a plan view illustrating sub-pixels according to one or more embodiments. FIG. 20 is a cross-sectional view illustrating a display panel according to one or more embodiments. For example, FIG. 20 illustrates one example of a cross section of the display panel 100 corresponding to the line X5-X5′ in FIG. 19. FIGS. 19 and 20 illustrate embodiments that differ from the embodiments of FIGS. 19 and 20 with respect to pixel electrodes PXE, common electrodes CE, and light emitting elements LE.

FIGS. 19 and 20 differ from the embodiments of FIGS. 17 and 18 in that the first sub-pixel SPX1, the second sub-pixel SPX2, the third sub-pixel SPX3, and the fourth sub-pixel SPX4 including the pixel have the same number of light emitting elements. When three or more sub-pixels constitute one pixel, the light emitting elements LE may be InGaN-based elements.

FIG. 19 illustrates one or more embodiments in which one unit pixel PX includes the first sub-pixel SPX1, the second sub-pixel SPX2, the third sub-pixel SPX3, and the fourth sub-pixel SPX4.

As shown in FIGS. 19 and 20, the first sub-pixel SPX1 may include a first-type light emitting element LE1 that emits first light, and the second sub-pixel SPX2 may include the first-type light emitting element LE1 for emitting the first light and a second wavelength conversion layer QDL2, the third sub-pixel SPX3 may include the first-type light emitting element LE1 for emitting the first light and a third wavelength conversion layer QDL3, and the fourth sub-pixel SPX4 may include a third-type light emitting element LE3 for emitting the third light and the third wavelength conversion layer QDL3. The second wavelength conversion layer QDL2 may include a base resin BRS and second wavelength conversion particles WCP2 that convert light in a blue wavelength band to (or into) light in a green wavelength band. The third wavelength conversion layer QDL3 may include a base resin BRS and third wavelength conversion particles WCP3 that convert light other than light of the red wavelength to (or into) light in a red wavelength band. Accordingly, the first sub-pixel SPX1 may emit the first light, the second sub-pixel SPX2 may emit the second light, and the third sub-pixel SPX3 and the fourth sub-pixel SPX4 may emit the third light.

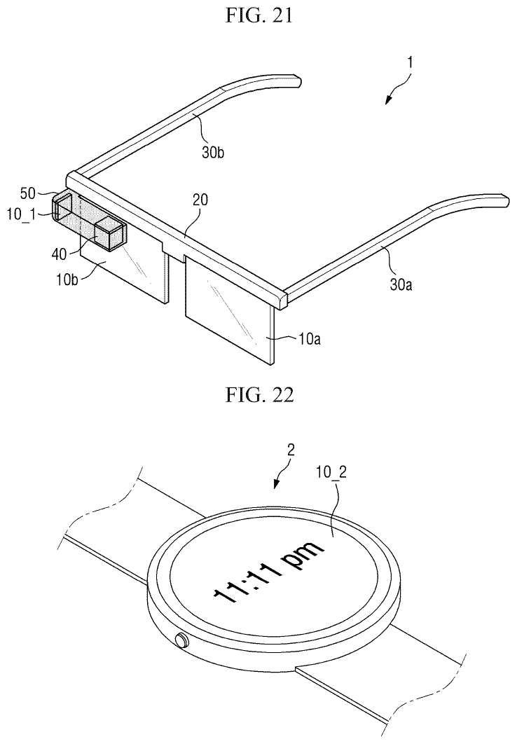

FIG. 21 is an example diagram illustrating a virtual reality device including a display device according to one or more embodiments. FIG. 21 illustrates a virtual reality device 1 in which the display device 10_1 according to one or more embodiments is used. The display device 10_1 may be any suitable one or more of the example display devices shown and described according to the present disclosure.

Referring to FIG. 21, the virtual reality device 1 according to one or more embodiments may be a device in a form of glasses. The virtual reality device 1 according to one or more embodiments may include a display device 10_1, a left-eye lens 10a, a right-eye lens 10b, a support frame 20, left and right legs 30a and 30b, a reflective member 40, and a display device housing 50.

FIG. 21 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 21, and may be applied in various forms and in various electronic devices as a person having ordinary skill in the art would appreciate.

The display device housing 50 may receive the display device 10_1 and the reflective member 40. An image displayed on the display device 10_1 may be reflected from the reflective member 40 and provided to a user's right eye through the right-eye lens 10b. Thus, the user may view a virtual reality image displayed on the display device 10 via the right eye.

FIG. 21 illustrates that the display device housing 50 is disposed at a right end of the support frame 20. However, one or more embodiments of the present disclosure are not limited thereto. For example, the display device housing 50 may be disposed at a left end of the support frame 20. In this case, the image displayed on the display device 10_1 may be reflected from the reflective member 40 and provided to the user's left eye via the left-eye lens 10a. Thus, the user may view the virtual reality image displayed on the display device 10_1 via the left eye. As another example, the display device housing 50 may be disposed at each of the left end and the right end of the support frame 20. In this case, the user may view the virtual reality image displayed on the respective display devices 10_1 via both the left eye and the right eye.

FIG. 22 is an example diagram illustrating a smart device including a display device according to one or more embodiments.

Referring to FIG. 22, a display device 10_2 according to one or more embodiments may be applied to a smart watch 2 as one of smart devices. The display device 10_2 may be any suitable one or more of the example display devices shown and described according to the present disclosure.

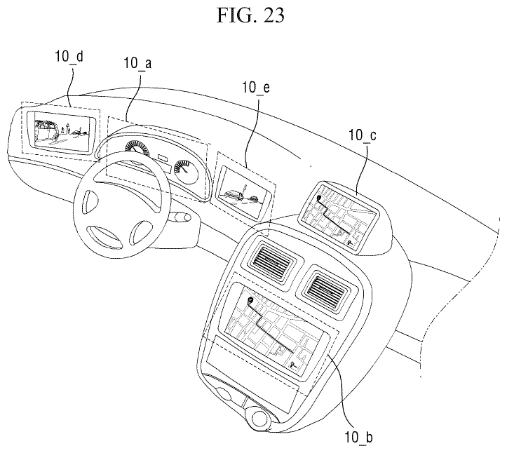

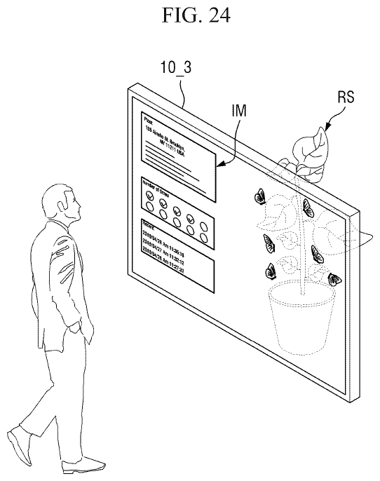

FIG. 23 is an example diagram illustrating a vehicle including a display device (or display devices) according to one or more embodiments. FIG. 23 illustrates a vehicle in which display devices according to an embodiment are used.

Referring to FIG. 23, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle. The display devices 10_a, 10_b, 10_c, 10_d and 10_e may be any suitable one or more of the example display devices shown and described according to the present disclosure. Further, two or more of the display devices 10_a, 10_b, 10_c, 10_d and 10_e may be formed as a single integrated display device including features and aspects according to one or more embodiments of the present disclosure.

FIG. 24 is an example diagram illustrating a transparent display device including a display device 10_3 according to one or more embodiments. The display device 10_3 may be any suitable one or more of the example display devices shown and described according to the present disclosure.

Referring to FIG. 24, a display device according to one or more embodiments may be applied to a transparent display device. The transparent display device may transmit light therethrough while displaying an image IM thereon. Therefore, a user located in front of the transparent display device may not only view the image IM displayed on the display device 10_3, but also view an object RS or a background located in rear of (or behind) the transparent display device. In case that the display device 10_3 is applied to the transparent display device, the substrate SUB of the display device shown in FIG. 8 (or the substrate SUB and/or other substrates shown and described herein) may include a light transmitting portion that may transmit light therethrough and/or may be made of a material that may transmit light therethrough.

In concluding the detailed description, those skilled in the art will appreciate that many variations and modifications can be made to the described embodiments of the present disclosure without substantially departing from the principles, spirit and/or scope of the present disclosure. Therefore, the disclosed embodiments of the present disclosure should be used in a generic and descriptive sense only and not for purposes of limitation.

What is claimed is:

1. A display device comprising:
a first sub-pixel comprising a first first-type light emitting element configured to emit light in a blue wavelength band, the first sub-pixel being configured to emit light in the blue wavelength band;
a second sub-pixel configured to emit light in a green wavelength band; and
a third sub-pixel comprising a second first-type light emitting element configured to emit light in the blue wavelength band, a third-type light emitting element configured to emit light in a red wavelength band, and a first wavelength conversion layer, the third sub-pixel being configured to emit light in the red wavelength band, a threshold voltage of the third-type light emitting element being lower than a threshold voltage of the second first-type light emitting element.

2. The display device of claim 1, wherein the second sub-pixel comprises a second-type light emitting element configured to emit light in the green wavelength band.

3. The display device of claim 1, wherein the second sub-pixel comprises a third first-type light emitting element configured to emit light in the blue wavelength band and a second wavelength conversion layer configured to convert light in the blue wavelength band to light in the green wavelength band.

4. The display device of claim 1, wherein a luminous efficiency of the second first-type light emitting element is higher than a luminous efficiency of the third-type light emitting element.

5. The display device of claim 1, further comprising:
a blue color filter corresponding to the first sub-pixel and configured to transmit only blue light;
a green color filter corresponding to the second sub-pixel and configured to transmit only green light; and
a red color filter corresponding to the third sub-pixel and configured to transmit only red light.

6. The display device of claim 5, wherein the first wavelength conversion layer is located between the second first-type light emitting element and the third-type light emitting element, and the red color filter, and comprises a wavelength conversion material configured to convert light in the blue wavelength band to light in the red wavelength band.

7. The display device of claim 6, wherein the wavelength conversion material comprises a quantum dot or a phosphor.

8. The display device of claim 5, wherein the first wavelength conversion layer is located between the second first-type light emitting element and the third-type light emitting element, and the red color filter, and comprises a wavelength conversion material configured to convert light in the blue wavelength band and light in the red wavelength band to light in a yellow wavelength band.

9. The display device of claim 1, wherein the third-type light emitting element comprises an InGaN-based element.

10. The display device of claim 1, wherein the third sub-pixel comprises a pixel electrode and a common electrode,
wherein the second first-type light emitting element and the third-type light emitting element are connected between the pixel electrode and the common electrode, and
wherein the second first-type light emitting element and the third-type light emitting element are connected in parallel.

11. The display device of claim 1, wherein the third sub-pixel comprises a pixel electrode and a common electrode,
wherein the pixel electrode and the common electrode are non-overlapping with each other in a thickness direction of the second first-type light emitting element and the third-type light emitting element,
wherein a portion of the second first-type light emitting element and a portion of the third-type light emitting element are on the pixel electrode, and
wherein another portion of the second first-type light emitting element and another portion of the third-type light emitting element are on the common electrode.

12. The display device of claim 1, wherein the third sub-pixel comprises a pixel electrode and a common electrode,
wherein the pixel electrode and the common electrode overlap each other in a thickness direction of the second first-type light emitting element and the third-type light emitting element,
wherein the second first-type light emitting element and the third-type light emitting element are on the pixel electrode, and
wherein the common electrode is on the second first-type light emitting element and the third-type light emitting element.

13. A display device comprising:
a first sub-pixel, a second sub-pixel, and a third sub-pixel that are configured to emit different color lights,
wherein the third sub-pixel comprises more diverse types of light emitting elements than the first sub-pixel, and
wherein the third sub-pixel comprises different types of light emitting elements that are configured to emit different color lights and have different threshold voltages.

14. A display device comprising:
a first sub-pixel comprising a first-type light emitting element configured to emit light in a blue wavelength band, the first sub-pixel being configured to emit light in the blue wavelength band;
a second sub-pixel configured to emit light in a green wavelength band;
a third sub-pixel comprising a third-type light emitting element configured to emit light in a red wavelength band, the third sub-pixel being configured to emit light in the red wavelength band; and
a fourth sub-pixel comprising a second first-type light emitting element configured to emit light in the blue wavelength band and a wavelength conversion layer, the fourth sub-pixel being configured to emit light in the red wavelength band, a threshold voltage of the third-type light emitting element being lower than a threshold voltage of the second first-type light emitting element.

15. The display device of claim 14, wherein the third sub-pixel and the fourth sub-pixel are adjacent to each other.

16. The display device of claim 14, wherein a luminous efficiency of the third-type light emitting element is lower than a luminous efficiency of the second first-type light emitting element.

17. The display device of claim 1, wherein the second sub-pixel comprises a second-type light emitting element configured to emit light in the green wavelength band.

18. The display device of claim 14, further comprising:
a blue color filter corresponding to the first sub-pixel and configured to transmit only blue light;
a green color filter corresponding to the second sub-pixel and configured to transmit only green light; and
a red color filter corresponding to the third sub-pixel and the fourth sub-pixel and configured to transmit only red light.

19. The display device of claim 18, wherein the wavelength conversion layer is located between the second first-type light emitting element and the red color filter, and comprises a wavelength conversion material configured to convert light in the blue wavelength band to light in the red wavelength band.

20. The display device of claim 14, wherein the third sub-pixel comprises a pixel electrode and a common electrode, and
wherein the third-type light emitting element is connected between the pixel electrode and the common electrode,
wherein the first type light emitting element and the third type light emitting element are connected in parallel.
